(19) United States
(12) Patent Application Publication
(10) Pub. No.: US 2023/0057630 A1
(43) Pub. Date: Feb. 23, 2023

(54) SEMICONDUCTOR DEVICE AND DATA STORAGE SYSTEM INCLUDING THE SAME

(71) Applicant: SAMSUNG ELECTRONICS CO., LTD., Suwon-si (KR)

(72) Inventors: Seongyeon WOO, Incheon (KR); Minje KIM, Seoul (KR); Woongseop LEE, Hwaseong-si (KR); Dongjun YU, Suwon-si (KR); Jinsoo LIM, Yongin-si (KR)

(21) Appl. No.: 17/870,200

(22) Filed: Jul. 21, 2022

(30) Foreign Application Priority Data
Aug. 19, 2021 (KR) 10-2021-0109433

(51) Int. Cl. H01L 27/11582; H01L 23/535; H01L 27/11573

(52) U.S. Cl. CPC H01L 27/11582; H01L 23/535; H01L 27/11573

(57) ABSTRACT

A device includes: a stack structure including first and second stack regions; first and second separation structures penetrating the stack structure; and vertical structures penetrating the stack structure, including first and second vertical memory structures spaced from the first separation structure by different lengths. The first and second vertical memory structures each include a lower portion, penetrating the first stack region, and an upper portion penetrating the second stack region. A first distance between a center of an upper region of the upper portion of the first vertical memory structure and a center of an upper region of the upper portion of the second vertical memory structure is different from a second distance between a center of an upper region of the lower portion of the first vertical memory structure and a center of an upper region of the lower portion of the second vertical memory structure.

### CROSS-REFERENCE TO RELATED APPLICATION

This application claims benefit of priority to Korean Patent Application No. 10-2021-0109433 filed on Aug. 19, 2021, in the Korean Intellectual Property Office, the disclosure of which is incorporated herein by reference in its entirety.

### BACKGROUND

### 1. Field

Embodiments relate to a semiconductor device and a data storage system including the same.

### 2. Description of the Related Art

A semiconductor device for storing high-capacity data may be used in an electronic system that uses data storage. As one method for increasing data storage capacity of a semiconductor device, a semiconductor device may include memory cells arranged three-dimensionally, instead of memory cells arranged two-dimensionally.

### SUMMARY

According to an embodiment, a semiconductor device includes: a base; a stack structure including a first stack region and a second stack region on the first stack region, on the base; first and a second separation structures penetrating through the stack structure in a vertical direction, perpendicular to an upper surface of the base, and parallel to each other, on the base; and vertical structures penetrating through the stack structure in the vertical direction, and between the first and second separation structures. Each of the first and second stack regions includes interlayer insulating layers and gate electrodes alternately and repeatedly stacked in the vertical direction. At least one of the gate electrodes in the first stack region includes a first wordline and at least one of the gate electrodes in the second stack region includes a second wordline. The vertical structures include a first vertical memory structure and a second vertical memory structure spaced apart from the first separation structure by different lengths. Each of the first and second vertical memory structures includes a lower vertical portion, penetrating through the first stack region, and an upper vertical portion extending from the lower vertical portion and penetrating through the second stack region. A first distance between a center of an upper region of the upper vertical portion of the first vertical memory structure and a center of an upper region of the upper vertical portion of the second vertical memory structure is different from a second distance between a center of an upper region of the lower vertical portion of the first vertical memory structure and a center of an upper region of the lower vertical portion of the second vertical memory structure.

According to an embodiment, a semiconductor device includes: a base; a stack structure including a first stack region and a second stack region on the first stack region, on the base; first and second separation structures penetrating through the stack structure in a vertical direction, perpendicular to an upper surface of the base, and parallel to each other, on the base; vertical memory structures penetrating through the stack structure in the vertical direction, and between the first and second separation structures; and bitline contact plugs electrically connected to the vertical memory structures on the vertical memory structures. Each of the first and second separation structures extends in a first direction, parallel to the upper surface of the base. Each of the first and second stack regions includes interlayer insulating layers and gate electrodes stacked alternately and repeatedly in the vertical direction. The vertical memory structures include: a first vertical memory structure spaced apart from the first separation structure by a first distance; a second vertical memory structure spaced apart from the first separation structure by a second distance greater than the first distance; a third vertical memory structure spaced apart from the first separation structure by a third distance, greater than the second distance; and a fourth vertical memory structure spaced apart from the first separation structure by a fourth distance, greater than the third distance. The first and third vertical memory structures are arranged in a second direction, perpendicular to the first direction. The second and fourth vertical memory structures are arranged in the second direction. In a top view, a first virtual axis passing through centers of the first and third vertical memory structures is spaced apart from a second virtual axis passing through centers of the second and fourth vertical memory structures in the first direction. Each of the first to fourth vertical memory structures includes a lower vertical portion, penetrating through the first stack region, and an upper vertical portion extending from the lower vertical portion and penetrating through the second stack region. A first distance between a center of an upper region of the upper vertical portion of the first vertical memory structure and a center of an upper region of the upper vertical portion of the second vertical memory structure is different from a second distance between a center of an upper region of the lower vertical portion of the first vertical memory structure and a center of an upper region of the upper vertical portion of the second vertical memory structure.

According to an embodiment, a data storage system includes: a semiconductor device including an input/output pad; and a controller electrically connected to the semiconductor device through the input/output pad and configured to control the semiconductor device. The semiconductor device includes: a base; a stack structure including a first stack region and a second stack region on the first stack region, on the base; first and second separation structures penetrating through the stack structure in a vertical direction, perpendicular to an upper surface of the base, and parallel to each other, on the base; vertical memory structures penetrating through the stack structure in the vertical direction, and between the first and second separation structures; and bitline contact plugs electrically connected to the vertical memory structures and on the vertical memory structures. Each of the first and second separation structures extends in a first direction, parallel to the upper surface of the base. Each of the first and second stack regions includes interlayer insulating layers and gate electrodes stacked alternately and repeatedly in the vertical direction. The vertical memory structures include: a first vertical memory structure spaced apart from the first separation structure by a first distance; a second vertical memory structure spaced apart from the first separation structure by a second distance greater than the first distance; a third vertical memory structure spaced apart from the first separation structure by a third distance greater than the second distance; and a fourth vertical memory structure spaced apart from the first separation structure by a fourth distance greater than the third distance. The first and third vertical memory structures are arranged in a second direction, perpendicular to the first direction. The second and fourth vertical memory structures are arranged in the second direction. In a top view, a first virtual axis passing through centers of the first and third vertical memory structures is spaced apart from a second virtual axis passing through centers of the second and fourth vertical memory structures in the first direction. Each of the first to fourth vertical memory structures includes a lower vertical portion, penetrating through the first stack region, and an upper vertical portion extending from the lower vertical portion and penetrating through the second stack region. A first distance between a center of an upper region of the upper vertical portion of the first vertical memory structure and a center of an upper region of the upper vertical portion of the second vertical memory structure is different from a second distance between a center of an upper region of the lower vertical portion of the first vertical memory structure and a center of an upper region of the upper vertical portion of the second vertical memory structure.

According to an embodiment, a semiconductor device includes: a base; a stack structure including a first stack region and a second stack region on the first stack region, on the base; first and second separation structures penetrating through the stack structure in a vertical direction, perpendicular to an upper surface of the base, and parallel to each other, on the base; vertical memory structures penetrating through the stack structures in the vertical direction, and between the first and second separation structures; and bitline contact plugs on the vertical memory structures and electrically connected to the vertical memory structures. Each of the first and second separation structures extends in a first direction, parallel to an upper surface of the base. Each of the first and second stack regions includes interlayer insulating layers and gate electrodes stacked alternately and repeatedly in the vertical direction. Each of the vertical memory structures includes a lower vertical portion, penetrating through the first stack region, and an upper vertical portion extending from the lower vertical portion and penetrating through the second stack region. In a top view, in at least one of the vertical structures, an upper region of the lower vertical portion is in a form of an ellipse having a major axis and a first minor axis, and an upper region of the upper vertical portion is in a form of an ellipse having a second major axis, intersecting the first major axis, and a second minor axis intersecting the first minor axis.

According to an embodiment, a semiconductor device, includes: a base; a stack structure including a first stack region on the base and a second stack region on the first stack region and including gate electrodes stacked in a vertical direction, perpendicular to an upper surface of the base; vertical memory structures penetrating through the stack structure in the vertical direction; and gate contact plugs in contact with gate pads of the gate electrodes. The gate contact plugs include a first gate contact plug and a second gate contact plug, each of the first and second gate contact plugs having a lower surface on a level lower than a level of the second stack region. Each of the first and second gate contact plugs includes a lower vertical portion, on a level lower than a level of the second stack region, and an upper vertical portion extending from the lower vertical portion and on a level higher than a level of the first stack region. A first distance between a center of an upper region of the upper vertical portion of the first gate contact plug and a center of an upper region of the upper vertical portion of the second gate contact plug is different from a second distance between a center of an upper region of the lower vertical portion of the first gate contact plug and a center of an upper region of the lower vertical portion of the second gate contact plug.

According to an embodiment, a data storage system includes: a semiconductor substrate; a peripheral interconnection including peripheral pads on the semiconductor substrate; a lower insulating structure covering the peripheral interconnection on the semiconductor substrate; a base on the lower insulating structure; a stack structure including a first stack region on the base and a second stack region on the first stack region and including gate electrodes stacked in a vertical direction, perpendicular to an upper surface of the base; vertical memory structures penetrating through the stack structure; and peripheral contact plugs electrically connected to the peripheral pads. In the peripheral contact plugs, a lower surface is on a level lower than a level of a lowermost gate electrode, among the gate electrodes, and an upper surface is on a level higher than a level of an uppermost gate electrode, among the gate electrodes. The peripheral contact plugs include a first peripheral contact plug and a second peripheral contact plug. Each of the first and second peripheral contact plugs a lower vertical portion, on a level lower than a level of the second stack region, and an upper vertical portion extending from the lower vertical portion and on a level higher than a level of the first stack region. A first distance between a center of an upper region of the upper vertical portion of the first peripheral contact plug and a center of an upper region of the upper vertical portion of the second peripheral contact plug is different from a second distance between a center of an upper region of the lower vertical portion of the first peripheral contact plug and a center of an upper region of the lower vertical portion of the second peripheral contact plug.

According to an embodiment, a semiconductor device includes: a semiconductor substrate; a peripheral interconnection including peripheral pads on the semiconductor substrate; a lower insulating structure covering the peripheral interconnection on the semiconductor substrate; a base on the lower insulating structure; a stack structure including a first stack region on the base and a second stack region on the first stack region and including gate electrodes stacked in a vertical direction, perpendicular to an upper surface of the base; vertical memory structures penetrating through the stack structure; and peripheral contact plugs electrically connected to the peripheral pads. In the peripheral contact plugs, a lower surface is on a level lower than a level of a lowermost gate electrode, among the gate electrodes, and an upper surface is on a level higher than a level of an uppermost gate electrode, among the gate electrodes. Each of the peripheral contact plugs includes a lower vertical portion, on a level lower than a level of the second stack region, and an upper vertical portion extending from the lower vertical portion and on a level higher than a level of the first stack region. In a top view, in at least one of the peripheral contact plugs, an upper region of the lower vertical portion is in a form of an ellipse having a first major axis and a first minor axis, and an upper region of the upper vertical portion is in a form of an ellipse having a second major axis, intersecting the first major axis, and a second minor axis intersecting the first minor axis.

### BRIEF DESCRIPTION OF DRAWINGS

Features will become apparent to those of skill in the art by describing in detail example embodiments with reference to the attached drawings in which:

FIGS. 1A, 1B, 2A, and 2B illustrate a semiconductor device according to example embodiments.

FIGS. 3A, 3B, and 3C are top views of a semiconductor device according to an example embodiment.

FIG. 4A is a top view of a modified example of a semiconductor device according to an example embodiment.

FIG. 4B is a top view of a modified example of a semiconductor device according to an example embodiment.

FIGS. 5A and 5B are top views of a modified example of a semiconductor device according to an example embodiment.

FIG. 6 is a top view of a modified example of a semiconductor device according to an example embodiment.

FIG. 7 is a top view of a modified example of a semiconductor device according to an example embodiment.

FIGS. 8A and 8B are top views of a modified example of a semiconductor device according to an example embodiment.

FIGS. 9A and 9B are top views of a modified example of a semiconductor device according to an example embodiment.

FIGS. 10A and 10B are top views of a modified example of a semiconductor device according to an example embodiment.

FIGS. 11A and 11B are top views of a modified example of a semiconductor device according to an example embodiment.

FIG. 12 is a top view of a modified example of a semiconductor device according to an example embodiment.

FIGS. 13A and 13B are top views of a modified example of a semiconductor device according to an example embodiment.

FIGS. 14, 15, 16A, 16B, 17, 18A, and 18B illustrate a modified example of a semiconductor device according to an example embodiment.

FIGS. 19A and 19B are top views of a modified example of a semiconductor device according to an example embodiment.

FIG. 20 is a top view of a modified example of a semiconductor device according to an example embodiment.

FIGS. 21 to 24 illustrate an example of a method of forming a semiconductor device according to an example embodiment.

FIG. 25 is a schematic diagram of an electronic system including a semiconductor device according to an example embodiment.

FIG. 26 is a schematic perspective view of a data storage system including a semiconductor device according to an example embodiment.

FIG. 27 is a schematic cross-sectional view of a data storage system including a semiconductor device according to an example embodiment.

### DETAILED DESCRIPTION

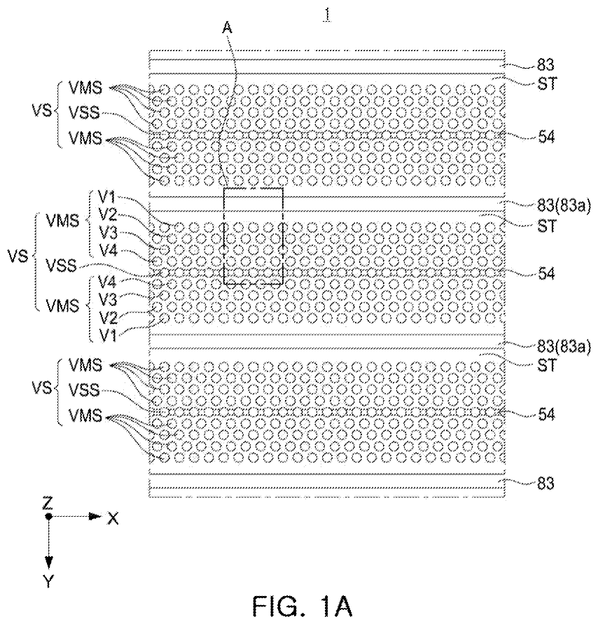

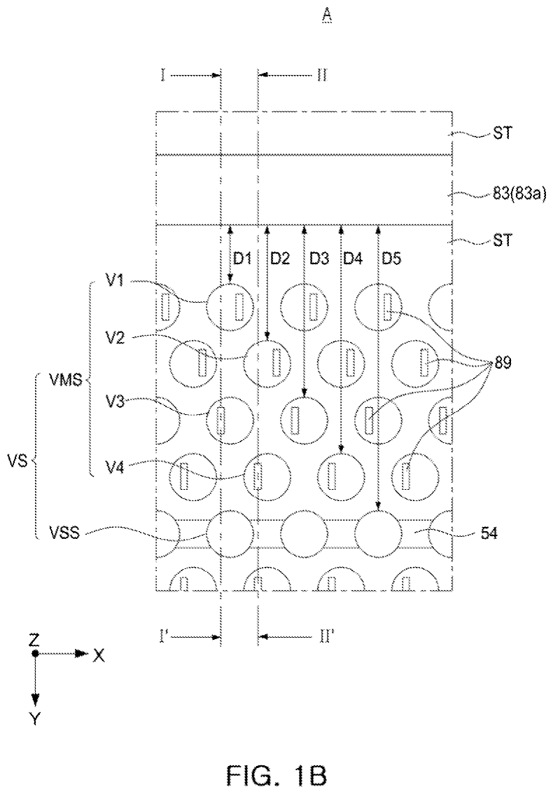

A semiconductor device according to an example embodiment will now be described with reference to FIGS. 1A, 1B, 2A, 2B, 3A, 3B, and 3C.

FIG. 1A is a schematic top view illustrating a semiconductor device according to an example embodiment.

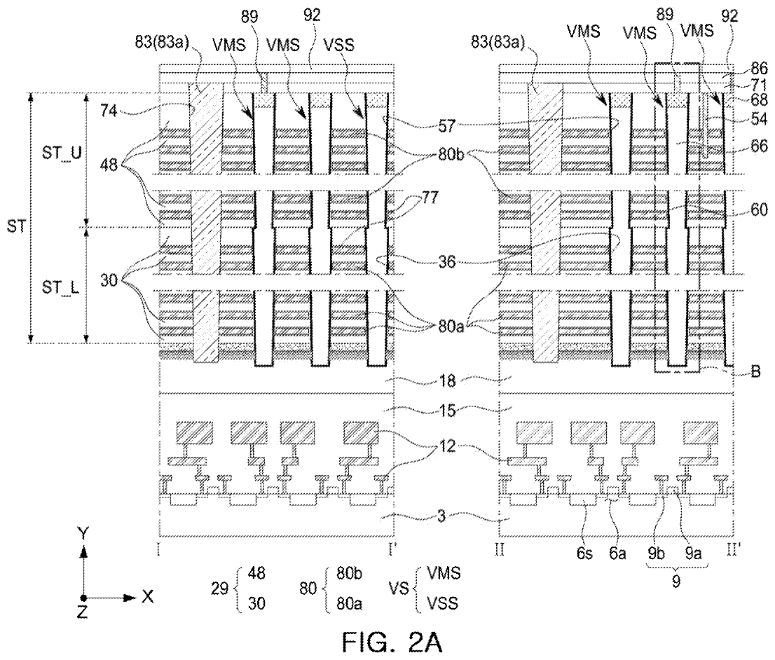

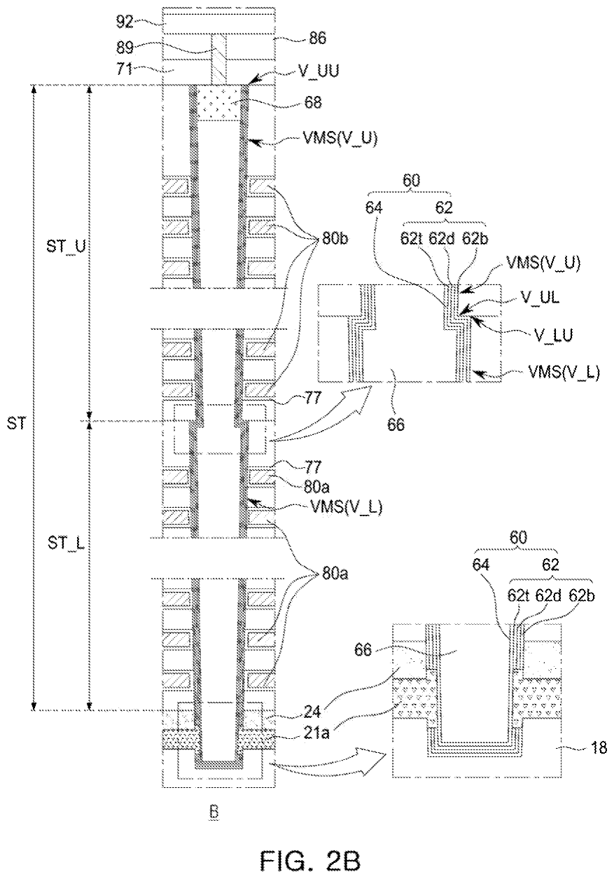

FIG. 1B is an enlarged top view of region “A” of FIG. 1A, FIG. 2A is a schematic cross-sectional view illustrating regions taken along lines I-I′ and II-II′ of FIG. 1.

FIG. 2B is an enlarged cross-sectional view of region “B” of FIG. 2A.

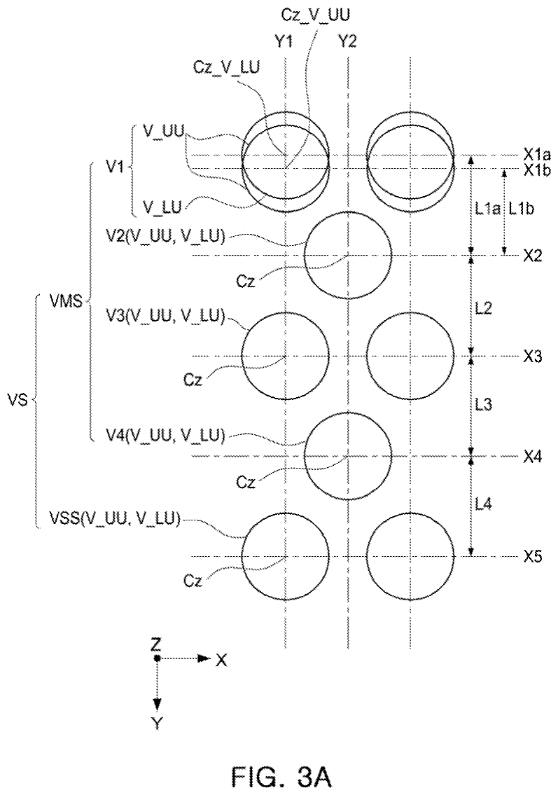

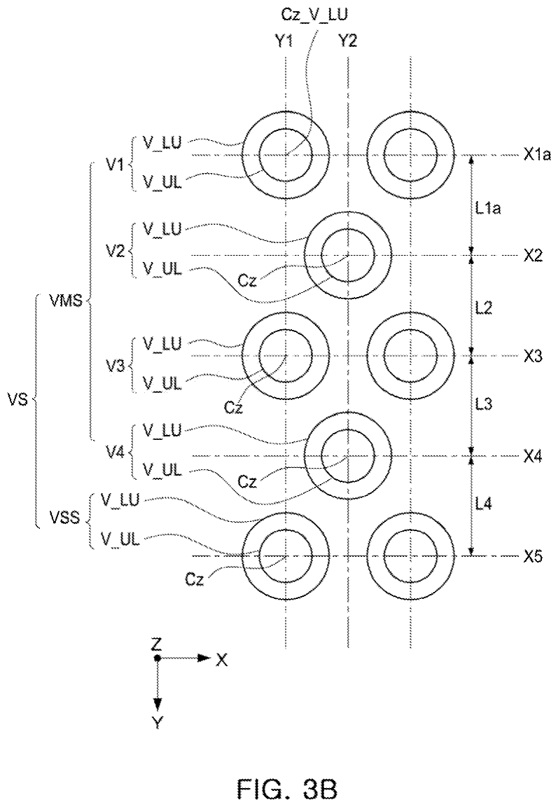

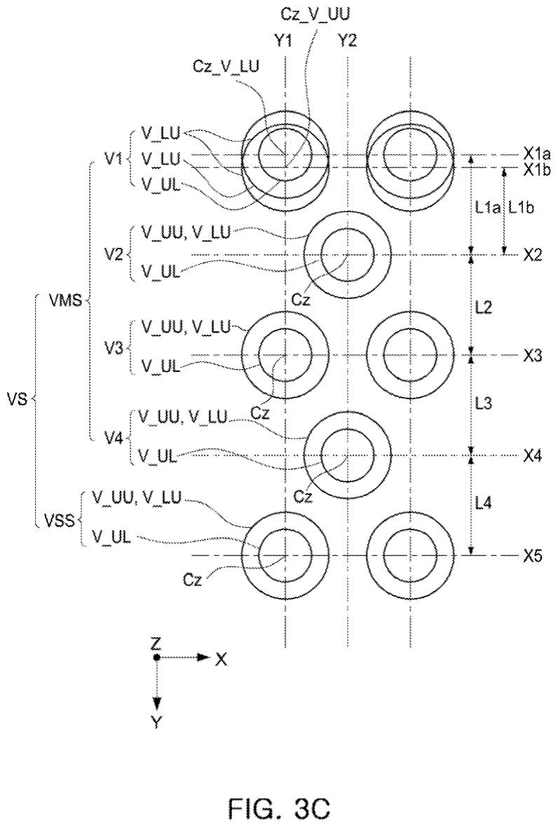

FIGS. 3A, 3B and 3C are top views illustrating some components of FIG. 1B. In detail, FIG. 3A is a top view of upper regions of upper vertical portions and upper regions of lower vertical portions, FIG. 3B is a top view of lower regions of the upper vertical portions and upper regions of the lower vertical portions, and FIG. 3C is a top view of upper regions of the upper vertical portion, upper regions of the lower vertical portions, and lower regions of the upper vertical portions.

Referring to FIGS. 1A, 1B, 2A and 2B, a semiconductor device 1 according to an example embodiment may include a base 18, a stack structure ST including a first stack region ST_L and a second stack region ST_U on the first stack region ST_L on the base 18, separation structures 83 on the base 18 and penetrating through the stack structure ST in a vertical direction Z, perpendicular to an upper surface of the base 18, and vertical structures VS penetrating through the stack structure ST in the vertical direction Z between the separation structures 83.

The semiconductor device 1 may further include a semiconductor substrate 3, a peripheral circuit 9, e.g., included in a peripheral circuit chip, on the semiconductor substrate 3, a peripheral interconnection 12, including peripheral pads, electrically connected to the peripheral circuit 9 on the semiconductor substrate 3, and a lower insulating layer 15, e.g., included in a lower insulating structure, covering the peripheral circuit 9 and the peripheral interconnection 12 on the semiconductor substrate 3. The peripheral circuit 9 may include a transistor including a gate 9a and source/drain regions 9b. The source/drain regions 9b may be in an active region 6a defined by an isolation region 6s on the semiconductor substrate 3. The gate 9a may be on the active region 6a between in the source/drain regions 9b.

The base 18 may be on the lower insulating layer 15. The base 18 may include at least one of a silicon layer and a metal layer. In an example, the base 18 may include a polysilicon layer having N-type conductivity. In another example, the base 18 may include a conductive layer, including at least one of a metal, a metal nitride, and a metal-semiconductor compound, and a polysilicon layer in contact with the conductive layer.

The semiconductor device 1 may further include a lower horizontal layer 21a and an upper horizontal layer 24 on the lower horizontal layer 21a. The lower horizontal layer 21a may include a silicon layer, e.g., a polysilicon layer having N-type conductivity. The upper horizontal layer 224 may include a silicon layer, e.g., a polysilicon layer having N-type conductivity.

The stack structure ST may include interlayer insulating layers 29 and gate electrodes 80 alternately stacked. The interlayer insulating layers 29 may be formed of an insulating material such as silicon oxide. The gate electrodes 80 may be formed of a conductive layer including at least one of a doped silicon layer, a metal nitride layer, a metal layer, and a metal-semiconductor compound layer.

In the stack structure ST, the first stack region ST_L may include lower interlayer insulating layers 30 and lower gate electrodes 80a alternately stacked in the vertical direction Z, and the second stack region ST_U may include upper interlayer insulating layers 48 and upper gate electrodes 80b alternately stacked in the vertical direction Z. The lower gate electrodes 80a may include first wordlines and the upper gate electrodes 80b may include second wordlines.

Among the lower interlayer insulating layers 30 and the lower gate electrodes 80a, a lowermost layer may be a lowermost lower interlayer insulating layer, and an uppermost layer may be an uppermost lower interlayer insulating layer. Among the upper interlayer insulating layers 48 and the upper gate electrodes 80b, a lowermost layer may be a lowermost upper interlayer insulating layer, and an uppermost layer may be an uppermost upper interlayer insulating layer.

The semiconductor device 1 may further include an upper separation pattern 54 penetrating through a portion of the second stack region ST_U. The upper separation pattern 54 may be formed of an insulating material such as silicon oxide. The upper separation pattern 54 may extend downwardly from an upper surface of the second stack region ST_U to penetrate through at least one or a plurality of upper gate electrodes, among the upper gate electrodes 80b.

The vertical structures VS may extend downwardly, while penetrating through the stack structure ST in the vertical direction Z, to penetrate through the lower and upper horizontal layers 21a and 24 and to extend into the base 18. The vertical structures VS may contact the silicon layer of the base 18.

The stack structure ST may cover upper and lower surfaces of each of the gate electrodes 80, and may further includes gate dielectrics 77 extending between the gate electrodes 80 and the vertical structures VS.

The vertical structures VS may include vertical memory structures VMS and vertical support structures VSS. The vertical support structures VSS may be formed simultaneously with the vertical memory structures VMS to have the same configuration as the vertical memory structures VMS. The vertical support structures VSS may be electrically dummy, and may serve as a support to prevent deformation of the stack structure ST.

Each of the vertical structures VS may include an insulating core region 66, liner layers 60 covering a side surface and a bottom surface of the insulating core region 66, and a pad pattern 68 on the insulating core region 66.

The liner layers 60 may include a channel layer 64 in contact with the insulating core region 66 and a dielectric structure 62 covering an outer surface and a bottom surface of the channel layer 64.

The dielectric structure 62 may include a first dielectric layer 62t, a second dielectric layer 62b, and a data storage layer 62d between the first dielectric layer 62t and the second dielectric layer 62b. The first dielectric layer 62t may contact the channel layer 64. The channel layer 64 may contact the pad pattern 68.

The first dielectric layer 62t may include silicon oxide or silicon oxide doped with impurities. The second dielectric layer 62b may include at least one of silicon oxide and a high-k dielectric material. The data storage layer 62d may include a material that can trap charges to store data, e.g., silicon nitride. The data storage layer 62d of each of the vertical memory structures VMS may include regions that may store data, e.g., as a flash memory device. The pad pattern 68 may include at least one of doped polysilicon, metal nitride (e.g., TiN, etc.), a metal (e.g., tungsten (W), etc.), and a metal-semiconductor compound (e.g., TiSi, etc.).

The lower horizontal layer 21a may penetrate through the dielectric structure 62 to contact the channel layer 64.

The semiconductor device 1 may further include a first upper insulating layer 71 and a second upper insulating layer 86 sequentially stacked on the stack structure ST.

The separation structures 83 may extend upwardly from a portion, penetrating through the stack structure ST, to penetrate through the first upper insulating layer 71, and may extend downwardly from the portion, penetrating through the stack structure ST, to penetrate through the lower and upper horizontal layers 21a and 24.

The semiconductor device 1 may further include bitline contact plugs 89 penetrating through the first and second upper insulating layers 71 and 86, and electrically connected to the vertical memory structures VMS. The bitline contact plugs 89 may be on the vertical memory structures VMS. The bitline contact plugs 89 may contact the pad patterns 68 of the vertical memory structures VMS. The vertical support structures VSS may be electrically separated from the bitline contact plugs 89.

The semiconductor device 1 may further include bitlines 92 electrically connected to the bitline contact plugs 89, and on the second upper insulating layer 86.

Each of the separation structures 83 may be in the form of a line extending in a first direction X, parallel to the upper surface of the base 18. The separation structures 83 may include a first separation structure 83a and a second separation structure 83b, parallel to and adjacent to each other.

Hereinafter, the vertical structures VS disposed between the first and second separation structures 83a and 83b will be mainly described.

In the vertical structures VS, the vertical memory structures VSS may include first vertical structure V1 spaced apart from the separation structures 83 by a first distance D1 and spaced apart from each other in the first direction X, second vertical structures V2 spaced apart from the separation structures 83 by a second distance D2, greater than the first distance D1, and spaced apart from each other in the first direction X, third vertical structures spaced apart from the separation structures 83 by a third distance D3, greater than the second distance D2, and spaced apart from each other in the first direction X, and fourth vertical structure V4 spaced apart from the separation structures 83 by a fourth distance D4, greater than the third distance D3, and spaced apart from each other in the first direction X.

In the vertical structures VS, the vertical support structures VSS may be spaced apart from the separation structures 83 by a fifth distance D5, greater than the fourth distance D3, and may be arranged to be spaced apart from each other in the first direction X. The vertical support structures VSS may be in an intermediate region between the first separation structure 83a and the second separation structure 83b.

The first and third vertical memory structures V1 and V3 and the vertical support structures VSS may be arranged in a second direction Y, perpendicular to the first direction X. The second and fourth vertical memory structures V2 and V4 may be arranged along the second direction Y.

In a top view, a first virtual vertical axis (Y1 of FIG. 3A), passing through centers of the first and third vertical memory structures V1 and V3 and the vertical support structures VSS and extending in the second direction Y, may be spaced apart from a second virtual vertical axis (Y2 of FIG. 3A) passing through centers of the second and fourth vertical memory structures V2 and V4 and extending in the second direction Y. The first virtual vertical axis (Y1 of FIG. 3A) and the second virtual vertical axis (Y2 of FIG. 3A) may be alternately and repeatedly arranged in the first direction X.

Each of the vertical structures VS may include a lower vertical portion V_L, penetrating through the first stack region ST_L, and an upper vertical portion V_U penetrating through the second stack region ST_U. A width of an upper region V_LU of the lower vertical portion V_L may be greater than a width of a lower region V_UL of the upper vertical portion V_U. A width of an upper region V_UU of the upper vertical portion V_U may be greater than a width of the lower region V_UL of the upper vertical portion V_U.

In the top view, in at least one of the vertical structures VS, the upper region V_LU of the lower vertical portion V_L may be circular, or, e.g., the upper region V_LU of the lower vertical portion V_L of at least one of the vertical structures VS may be elliptical.

In the top view, in at least one of the vertical structures VS, the upper region V_UU of the upper vertical portion V_U may be circular, or, e.g., the upper region V_UU of the upper vertical portion V_U of at least one of the vertical structures VS may be elliptical.

In the top view, in at least one of the vertical structures VS, the lower region V_UL of the upper vertical portion V_U may be circular, or, e.g., the lower region V_UL of the upper vertical portion V_U of at least one of the vertical structures VS may be elliptical.

Hereinafter, for better understanding, descriptions will be mainly provided for a single first vertical memory structure V1 adjacent to the first separation structure 83a, among the first vertical memory structures V1, a single second vertical memory structures V2 among the second vertical memory structures V2, a single third vertical memory structure V3 among the third vertical memory structures V3, a single fourth vertical memory structures V4 among the fourth vertical memory structures V4, and a single vertical support structure VSS among the vertical support structures VSS. In the top view, the second vertical memory structure V2 may be adjacent to the first vertical memory structure V1 in a first oblique direction inclined with respect to the first direction X, the third vertical memory structure V3 may be adjacent to the second vertical memory structure V2 in a second diagonal direction inclined with respect to the first direction X and having an orientation different from an orientation of the first diagonal direction, the fourth vertical memory structure V4 may be adjacent to the third vertical memory structure V3 in the first diagonal direction, and the vertical support structure VSS may be adjacent to the fourth vertical memory structure V4 in the second diagonal direction.

In the top view, the first and third vertical memory structures V1 and V3 and the vertical support structure VSS may be arranged in the second direction Y, and the second and fourth vertical memory structures V2 and V4 may be arranged in the second direction Y. In the top view, a first virtual vertical axis (Y1 of FIG. 3A), passing through centers of the first and third vertical memory structures V1 and V3 and the vertical support structures VSS and extending in the second direction Y, may be spaced apart from the second virtual vertical axis (Y2 of FIG. 3A) passing through centers of the second and fourth vertical memory structures V2 and V4 and extending in the second direction Y.

In example embodiments, each of the first to fourth vertical memory structures V1, V2, V3, and V4 and the vertical support structure VSS may include the lower vertical portion (V_L of FIG. 2B) of the upper region V_LU, the lower region V_UL of the upper vertical portion (V_U of FIG. 2B), and the upper region V_UU of the upper vertical portion (V_U of FIG. 2B), as illustrated in FIG. 2B. However, as will be described below, there may be various top views of the first to fourth vertical memory structures V1, V2, V3, and V4 and the vertical support structure VSS.

Top views of the upper region V_LU of the lower vertical portion (V_L of FIG. 2B), the lower region V_UL of the upper vertical portion (V_U of FIG. 2B), and the upper region V_UU of the upper vertical portion (V_U of FIG. 2B) in the first to fourth vertical memory structures V1, V2, V3, and V4 and the vertical support structure VSS will now be described VSS with reference to FIGS. 3A, 3B, and 3C together with FIG. 2B.

FIG. 3A is a top view illustrating the upper region V_LU of the lower vertical portion (V_L of FIG. 2B) and the upper region V_UU of the upper vertical portion (V_U of FIG. 2B) of each of the first to fourth vertical memory structures V1, V2, V3 and V4 and the vertical support structure VSS.

FIG. 3B is a top view illustrating the upper region V_LU of the lower vertical portion (V_L of FIG. 2B) and the lower region V_UL of the upper vertical portion (V_U of FIG. 2B) of each of the first to fourth vertical memory structures V1, V2, V3 and V4 and the vertical support structure VSS.

FIG. 3C is a top view illustrating the upper region V_LU of the lower vertical portion (V_L of FIG. 2B), the lower region V_UL of the upper vertical portion (V_U of FIG. 2B), and the upper region V_UU of the upper vertical portion (V_U of FIG. 2B) of each of the first to fourth vertical memory structures V1, V2, V3 and V4 and the vertical support structure VSS.

Referring to FIGS. 3A and 3C together with FIG. 2B, in top views, a first center Cz_V_LU of the upper region V_LU of the lower vertical portion (V_L of FIG. 2B) of the first vertical memory structure V1 and a second center Cz_V_UU of the upper region V_UU of the upper vertical portion (V_U of FIG. 2B) of the first vertical memory structure V1) may be spaced apart from each other. For example, the second center Cz_V_UU may be spaced apart from the first center Cz_V_LU in a direction away from the first separation structure 83a, e.g., in the second direction Y.

A distance between the first center Cz_V_LU and the second center Cz_V_UU may be a distance in a layout formed using a CAD program in a computer system before a semiconductor process is performed.

The distance between the first center Cz_V_LU and the second center (Cz_V_UU) may include a distance in a layout formed using a CAD program in a computer system before performing a semiconductor process and a distance caused by an allowable process error range after performing semiconductor processes such as a photolithography process and an etching process.

In a top view, a center Cz of the upper region V_LU of the lower vertical portion (V_L of FIG. 2B) of each of the second to fourth vertical memory structures V2, V3, and V4 and a center Cz of the upper region V_UU of the upper vertical portion (V_U of FIG. 2B) of each of the second to fourth vertical memory structures V2, V3, and V4 may overlap each other, and a center Cz of the upper region V_LU of the lower vertical portion (V_L of FIG. 2B) of the vertical support structure VSS and a center Cz of the upper region V_UU of the upper vertical portion (V_U of FIG. 2B) of the vertical support structure VSS may overlap each other.

The center Cz of the upper region V_LU of the lower vertical portion (V_L of FIG. 2B) of the vertical support structure VSS and the center Cz of the upper region V_UU of the upper vertical portion (V_U of FIG. 2B) of the vertical support structure VS_S of each of the second to fourth vertical memory structures V2, V3, and V4 may match each other in a layout formed using a CAD program in a computer system before performing a semiconductor process.

The center Cz of the upper region V_LU of the lower vertical portion (V_L of FIG. 2B) of the vertical support structure VSS and the center Cz of the upper region V_UU of the upper vertical portion (V_U of FIG. 2B) of the vertical support structure VS_S of each of the second to fourth vertical memory structures V2, V3, and V4 may be spaced apart from each other within an allowable process error range after performing semiconductor processes such as a photolithography process and an etching process.

Accordingly, in the top view, a distance between the first center Cz_V_LU of the upper region V_LU of the lower vertical portion (V_L of FIG. 2B) of the first vertical memory structure V1 and the second center Cz_V_UU of the upper region V_UU of the upper vertical portion (V_U of FIG. 2B) of the first vertical memory structure V1 may be greater than a distance between the center Cz of the upper region V_LU of the lower vertical portion (V_L of FIG. 2B) of each of the second to fourth vertical memory structures V2, V3, and V4 and the center Cz of the upper region V_UU of the upper vertical portion (V_U of FIG. 2B) of each of the second to fourth vertical memory structures V2, V3, and V4. For example, in the top view, the distance between the first center Cz_V_LU and the second center Cz_V_UU may be greater than a distance between the center Cz of the upper region V_LU of the lower vertical portion (V_L of FIG. 2B) of the second vertical memory structure V2 and the center Cz of the upper region V_UU of the upper vertical portion (V_U of FIG. 2B) of the second vertical memory structure V2.

In a top view, there may be a first virtual horizontal axis X1a passing through the first center Cz_V_LU of the upper region V_LU of the lower vertical portion (V_L of FIG. 2B) of the first vertical memory structure V1 and extending in the first direction X, a second virtual horizontal axis X2 passing through the center Cz of the upper region V_LU of the lower vertical portion (V_L of FIG. 2B) of the second vertical memory structure V2 and extending in the first direction X, a third virtual horizontal axis X3 passing through the center Cz of the upper region V_LU of the lower vertical portion (V_L of FIG. 2B) of the third vertical memory structure V3 and extending in the first direction X, a fourth virtual horizontal axis X4 passing through the center Cz of the upper region V_LU of the lower vertical portion (V_L of FIG. 2B) of the fourth vertical memory structure V4 and extending in the first direction X, and a fifth virtual horizontal axis X5 passing through the center Cz of the upper region V_LU of the lower vertical portion (V_L in FIG. 2B) of the vertical support structure VS_S and extending in the first direction X.

In the top view, there may be a sixth virtual horizontal axis X1b passing through the second center Cz_V_UU of the upper region V_UU of the upper vertical portion (V_U of FIG. 2B) of the first vertical memory structure V1 and extending in the first direction X.

A distance between the first virtual horizontal axis (now denoted as X1a) and the sixth virtual horizontal axis X1b may be the same as a distance between the first center Cz_V_LU and the second center Cz_V_UU.

A first distance L1a between the first virtual horizontal axis X1a and the second virtual horizontal axis X2, a second distance L2 between the second virtual horizontal axis X2 and the third virtual horizontal axis X3, a third distance L3 between the third virtual horizontal axis X3 and the fourth virtual horizontal axis X4, and a fourth distance L4 between the fourth virtual horizontal axis X4 and the fifth virtual horizontal axis X5 may be substantially the same.

The first distance L1a between the first virtual horizontal axis X1a and the second virtual horizontal axis X2 may be greater than a distance L1b between the sixth virtual horizontal axis X1b and the second virtual horizontal axis X2.

Referring to FIGS. 3B and 3C together with FIG. 2B, in a top view, a width of the lower region V_UL of the upper vertical portion (V_U of FIG. 2B) of each of the first to fourth vertical memory structures V1, V2, V3, and V4 and the vertical support structure VSS may be smaller than a width of the upper region V_LU of the lower vertical portion (V_L of FIG. 2B) of each of the first to fourth vertical memory structures V1, V2, V3, and V4 and the vertical support structure VSS.

In the top view, the lower region V_UL of the upper vertical portion (V_U of FIG. 2B) of each of the first to fourth vertical memory structures V1, V2, V3, and V4 and the vertical support structure VSS may be in the upper region V_LU of the lower vertical portion (V_L of FIG. 2B) of each of the first to fourth vertical memory structures V1, V2, V3, and V4 and the vertical support structure VSS. For example, in the top view, the lower region V_UL of the upper vertical portion (V_U of FIG. 2B) of the first vertical memory structure V1 may be in the upper region V_LU of the lower vertical portion (V_L of FIG. 2B) of the first vertical memory structure V1.

In the top view, a center of the lower region V_UL of the upper vertical portion (V_U of FIG. 2B) of each of the first to fourth vertical memory structures V1, V2, V3, and V4 and the vertical support structure VSS may match a center of the upper region V_LU of the lower vertical portion (V_L of FIG. 2B) of each of the first to fourth vertical memory structures V1, V2, V3, and V4 and the vertical support structure VSS.

In the top view, the center of the lower region V_UL of the upper vertical portion (V_U of FIG. 2B) of each of the first to fourth vertical memory structures V1, V2, V3, and V4 and the vertical support structure VSS and the center of the upper region V_LU of the lower vertical portion (V_L of FIG. 2B) of each of the first to fourth vertical memory structures V1, V2, V3, and V4 and the vertical support structure VSS may be spaced apart from each other within an allowable process error range after performing semiconductor processes such as a photolithography process and an etching process.

In the top view, the center Cz_V_LU of the lower region V_UL of the upper vertical portion (V_U of FIG. 2B) of the first vertical memory structure V1) may be spaced apart from the center Cz_V_UU of the upper region V_UU of the upper vertical portion (V_U of FIG. 2B) of the first vertical memory structure V1. For example, the center Cz_V_UU of the upper region V_UU of the upper vertical portion (V_U of FIG. 2B) of the first vertical memory structure V1 may be spaced apart from the center Cz_V_LU of the lower region V_UL of the upper vertical portion (V_U of FIG. 2B) of the first vertical memory structure V1 in a direction away from the first separation structure 83a of FIG. 1B, e.g., in the second direction Y.

Various modified examples of the semiconductor device 1 according to example embodiments will now be described.

Hereinafter, the same numerals may refer to the same component. Thus, in the following description of the modified examples, descriptions of components overlapping with the above-described components will be omitted, and description will be provided based on components which are modified or which are to be replaced.

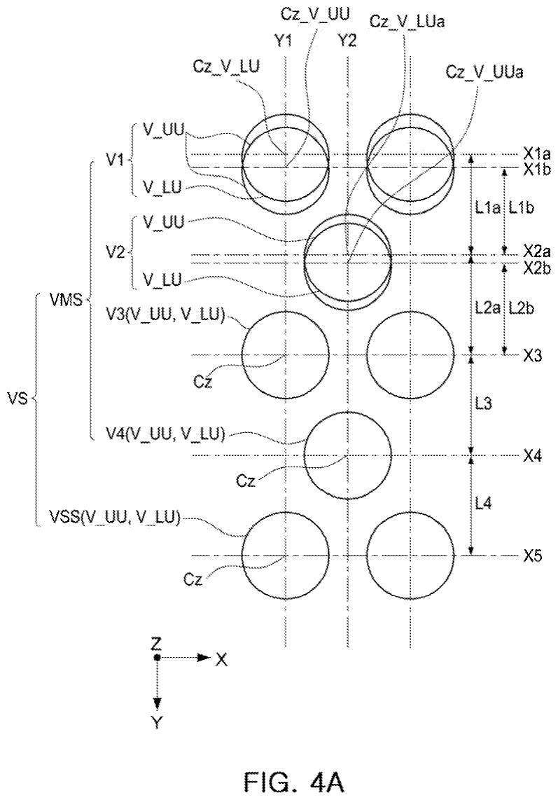

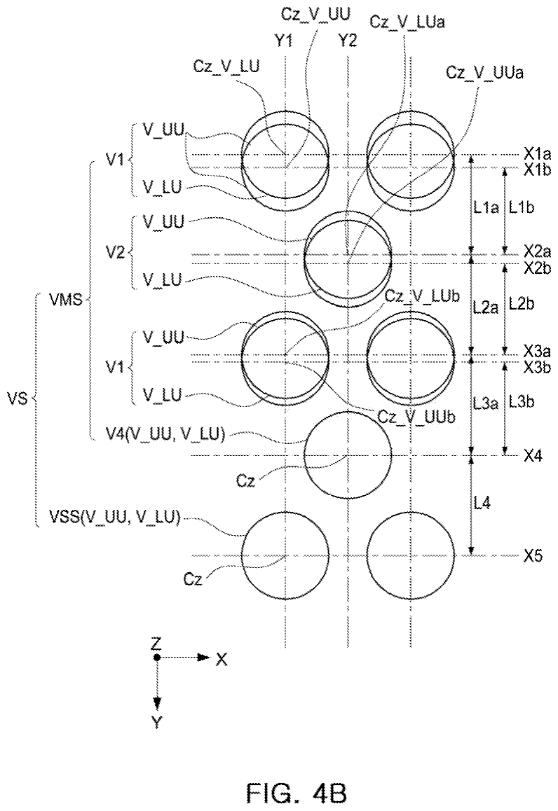

A modified example of the second vertical memory structure V2 described with reference to FIGS. 3A to 3C will now be described with reference to FIG. 4A.

FIG. 4A is a top view illustrating the upper region V_LU of the lower vertical portion (V_L of FIG. 2B) and the upper region V_UU of the upper vertical portion (V_U in FIG. 2B) of each of the first to fourth vertical memory structures V1, V2, V3, and V4 and the vertical support structure VSS. FIG. 4A illustrates a modified example of the second vertical memory structure V2 of FIG. 3A.

In the modified example, referring to FIG. 4A, in the top view, a third center Cz_V_LUa of the upper region V_LU of the lower vertical portion (V_L of FIG. 2B) of the second vertical memory structure V2 and a fourth center Cz_V_UUa of the upper region V_UU of the upper vertical portion V_U of FIG. 2B of the second vertical memory structure V2 may be spaced apart from each other. For example, the fourth center Cz_V_UUa may be spaced apart from the third center Cz_V_LUa in a direction away from the first separation structure 83a, e.g., in the second direction Y.

A distance between the fourth center Cz_V_UUa and the third center Cz_V_LUa may be smaller than a distance between the first center Cz_V_UU and the second center Cz_V_LU as illustrated in FIG. 3A.

There may be a second virtual horizontal axis X2a, passing through the third center Cz_V_LUa of the upper region V_LU of the lower vertical portion (V_L of FIG. 2B) of the second vertical memory structure V2 and extending in the first direction X, and a seventh virtual horizontal axis X2b passing through the fourth center Cz_V_UUa of the upper region V_UU of the upper vertical portion (V_U of FIG. 2B) of the second vertical memory structure V2 and extending in the first direction X.

A distance between the second virtual horizontal axis X2a and the seventh virtual horizontal axis X2b may be substantially the same as a distance between the fourth center Cz_V_UUa and the third center Cz_V_LUa.

A distance L2a between the second virtual horizontal axis X2a and the third virtual horizontal axis X3 may be substantially the same as a distance between the first virtual horizontal axis X1a and the second virtual horizontal axis X2a.

A distance L2b between the seventh virtual horizontal axis X2b and the third virtual horizontal axis X3 may be the greater than the distance L1b between the sixth virtual horizontal axis X1b and the second virtual horizontal axis X2a.

A modified example of the second and third vertical memory structures V2 and V3 described with reference to FIGS. 3A to 3C will now be described with reference to FIG. 4B.

FIG. 4B is a top view illustrating the upper region V_LU of the lower vertical portion (V_L of FIG. 2B) and an upper region (V_UU) of the upper vertical portion (V_U in FIG. 2B) of each of the first to fourth vertical memory structures V1, V2, V3, and V4 and the vertical support structure VSS. FIG. 4B illustrates a modified example of the third vertical memory structure V3 of FIG. 4A.

In the modified example, referring to FIG. 4B, in a top view, the same second vertical memory structure V2 as illustrated in FIG. 4A may be provided. In the top view, a fifth center Cz_V_LUb of the upper region V_LU of the lower vertical portion (V_L of FIG. 2B) of the third vertical memory structure V3 and a sixth center Cz_V_UUb of the upper region V_UU of the upper vertical portion (V_U of FIG. 2B) of the third vertical memory structure V3 may be spaced apart from each other. For example, the fifth center Cz_V_LUb may be spaced apart from the sixth center Cz_V_UUb in a direction away from the first separation structure 83a, e.g., in the second direction Y.

A distance between the fifth center Cz_V_LUb and the sixth center Cz_V_UUb may be smaller than a distance between the fourth center Cz_V_UUa and the third center Cz_V_LUa as illustrated in FIG. 4A.

There may be a third virtual horizontal axis X3a, passing through the fifth center Cz_V_LUb of the upper region V_LU of the lower vertical portion (V_L in FIG. 2B) of the third vertical memory structure V3 and extending in the first direction X, and an eighth virtual horizontal axis X3b passing through the sixth center Cz_V_UUb of the upper region V_UU of the upper vertical portion (V_U in FIG. 2B) of the third vertical memory structure V3 and extending in the first direction X.

A distance between the third virtual horizontal axis X3a and the eighth virtual horizontal axis X3b may be substantially the same as a distance between the fifth center Cz_V_LUb and the sixth center Cz_V_UUb.

A distance L3a between the third virtual horizontal axis X3a and the fourth virtual horizontal axis X4 may be substantially the same as a distance between the first virtual horizontal axis X1a and the second virtual horizontal axis X2a.

A distance L3b between the eighth virtual horizontal axis X3b and the fourth virtual horizontal axis X4 may be greater than the distance L2b between the seventh virtual horizontal axis X2b and the third virtual horizontal axis X3a.

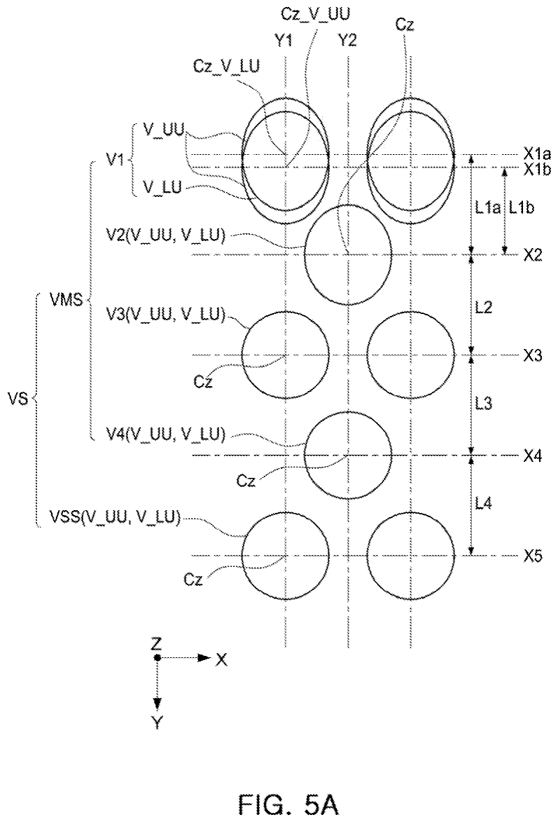

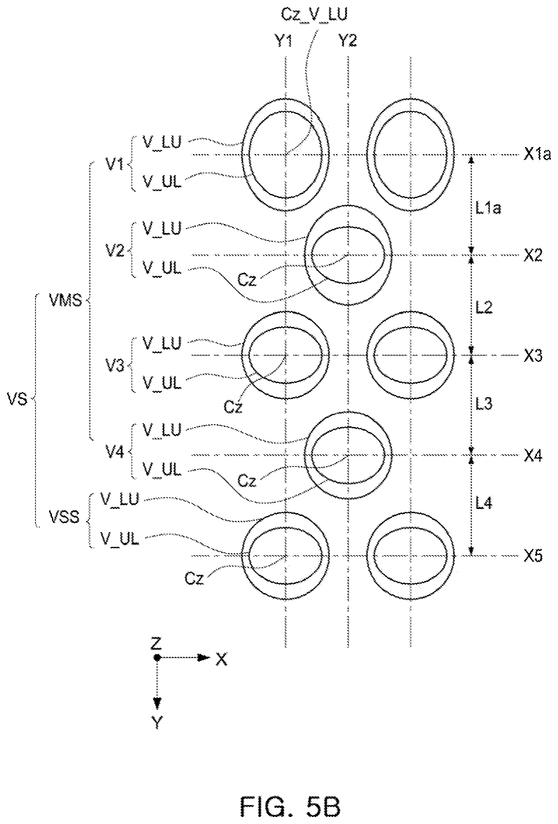

A modified example of the first and second vertical memory structures V1 and V2 described with reference to FIG. 3A will now be described with reference to FIG. 5A.

FIG. 5A is a top view illustrating the upper region V_LU of the lower vertical portion (V_L of FIG. 2B) and the upper region V_UU of the upper vertical portion (V_U in FIG. 2B) of each of the first to fourth vertical memory structures V1, V2, V3, and V4 and the vertical support structure VSS. FIG. 5A illustrates a modified example of the first and second vertical memory structures V1 and V2 of FIG. 3A.

In the modified example, referring to FIG. 5A, in the top view, a maximum width of the upper region V_LU of the lower vertical portion (V_L in FIG. 2B) of the first vertical memory structure V1 may be greater than a maximum width of the upper region V_LU of the lower vertical portion (V_L of FIG. 2B) of at least one of the four vertical memory structures V2, V3, and V4. In the top view, a maximum width of the upper region V_LU of the lower vertical portion (V_L in FIG. 2B) of the first vertical memory structure V1 may be greater than a maximum width of the upper region V_LU of the lower vertical portion (V_L of FIG. 2B) of the vertical support structure VSS.

In the top view, a maximum width of the upper region V_LU of the lower vertical portion (V_L in FIG. 2B) of the second vertical memory structure V2 may be greater than a maximum width of the upper region V_LU of the lower vertical portions (V_L of FIG. 2B) of at least one of the third and fourth vertical memory structures V3 and V4.

In the top view, a maximum width of the upper region V_LU of the lower vertical portion (V_L of FIG. 2B) of the third vertical memory structure V3, a maximum width of the upper region V_LU of the lower vertical portion (V_L of FIG. 2B) of the fourth vertical memory structure V4 in FIG. 2B, and a maximum width of the upper region V_LU of the lower vertical portion (V_L of FIG. 2B) of the vertical support structure VSS may be substantially the same.

In the top view, a maximum width of the upper region V_UU of the upper vertical portion (V_U of FIG. 2B) of the first vertical memory structure V1 may be greater than a maximum width of the upper region V_UU of the upper vertical portion (V_U of FIG. 2B) of at least one of the second to fourth vertical memory structures V2, V3, and V4. In the top view, a maximum width of the upper region V_UU of the upper vertical portion (V_U of FIG. 2B) of the first vertical memory structure V1 may be greater than a maximum width of the upper region V_UU of the upper vertical portion (V_U of FIG. 2B) of the vertical support structure VSS.

In the top view, a maximum width of the upper region V_UU of the upper vertical portion (V_U in FIG. 2B) of the second vertical memory structure V2 may be greater than a maximum width of the upper region V_UU of the upper vertical portion (V_U of FIG. 2B) of at least one of the third and fourth vertical memory structures V3 and V4.

In the top view, the maximum width of the upper region V_UU of the upper vertical portion (V_U in FIG. 2B) of the third vertical memory structure V3, the maximum width of the upper region V_UU of the upper vertical portion (V_U of FIG. 2B) of the fourth vertical memory structure V4, and a maximum width of the upper region V_UU of the upper vertical portion (V_U of FIG. 2B) of the vertical support structure VSS may be substantially the same.

In the top view, the upper region V_LU of the lower vertical portion (V_L of FIG. 2B) of the first vertical memory structure V1 may be elliptical. For example, a major-axis direction of the upper region V_LU of the lower vertical portion (V_L of FIG. 2B) of the first vertical memory structure V1 may be the second direction Y.

In the top view, the upper region V_UU of the upper vertical portion (V_U of FIG. 2B) of the first vertical memory structure V1 may be elliptical. For example, a major-axis direction of the upper region V_UU of the upper vertical portion (V_U of FIG. 2B) of the first vertical memory structure V1 may be the second direction Y.

In the top view, the upper region V_LU of the lower vertical portion (V_L of FIG. 2B) of the second vertical memory structure V2 and the upper region V_UU of the upper vertical portion (V_U in FIG. 2B) of the second vertical memory structure V2 may each be elliptical. For example, the upper region V_LU of the lower vertical portion (V_L of FIG. 2B) of the second vertical memory structure V2 and the upper region V_UU of the upper vertical portion (V_U in FIG. 2B) of the second vertical memory structure V2 may each be in the form of an ellipse having a major axis in the second direction Y.

A modified example of the first to fourth vertical memory structures V1, V2, V3, and V4 and the vertical support structure VSS described with reference to FIG. 3B will now be described with reference to FIG. 5B.

FIG. 5B is a top view illustrating the upper region V_LU of the lower vertical portion (V_L in FIG. 2B) and the lower region V_UL of the upper vertical portion (V_U in FIG. 2B) of each of the first to fourth vertical memory structures V1, V2, V3, and V4 and the vertical support structure VSS. FIG. 5B illustrates a modified example of the upper region V_LU of the lower vertical portion (V_L of FIG. 2B) and the lower region V_UL of the upper vertical portion (V_U of FIG. 2B) in each of the first to fourth vertical memory structures V1, V2, V3, and V4 and the vertical support structure VSS described in FIG. 3B.

In the modified example, referring to FIG. 5B, in the top view, a shape of the upper region V_LU of the lower vertical portion (V_L of FIG. 2B) of each of the first to fourth vertical memory structures V1, V2, V3, and V4 and the vertical support structure VSS and a shape of the upper region (V_UU of FIG. 5A) of the upper vertical portion (V_U of FIG. 2B) of each of the first to fourth vertical memory structures V1, V2, V3, and V4 and the vertical support structure VSS may be the same as those described with reference to FIG. 5A.

In the top view, the lower region V_UL of the upper vertical portion V_U of at least one of the first to fourth vertical memory structures V1, V2, V3, and V4 and the vertical support structure VSS may be elliptical. The lower region V_UL of a plurality of upper vertical portions V_U, among the first to fourth vertical memory structures V1, V2, V3, and V4 and the vertical support structure VSS, may be elliptical.

In the top view, a major-axis direction of the lower region V_UL of the upper vertical portion V_U of a vertical structure having an elliptical shape, among the first to fourth vertical memory structures V1, V2, V3, and V4 and the vertical support structure VSS, may have an orientation intersecting a major-axis direction of the lower region V_UL of the upper vertical portion V_U of another vertical structure having an elliptical shape. For example, the lower region V_UL of the upper vertical portion V_U of the first vertical memory structure V1 may be in the form of an ellipse having a first major axis, and the lower region V_UL of the upper vertical portion V_U of the second vertical memory structure V2 may be in the form of an ellipse having a second major axis, different from the first major axis. The first long axis may extend in the second direction Y. The second long axis may extend in the first direction X.

The lower region V_UL of the upper vertical portion V_U of each of the third and fourth vertical memory structures V3 and V4 and the vertical support structure VSS may be in the form of an ellipse having the second major axis.

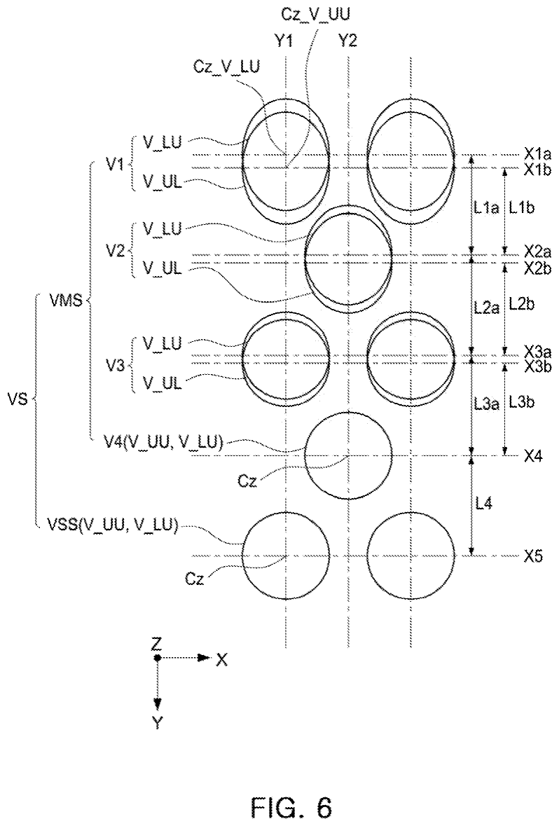

A modified example of the first and second vertical memory structures V1 and V2 in FIG. 4B will now be described with reference to FIG. 6.

FIG. 6 is a top view illustrating a modified example of shapes of the upper region V_LU of the lower vertical portion (V_L in FIG. 2B) and the upper region V_UU of the upper vertical portion (V_U in FIG. 2B) of each of the first and second vertical memory structures V1 and V2 in the top view of FIG. 4B.

In the modified example, referring to FIG. 6, in the top view of FIG. 4B, the upper region V_LU of the lower vertical portion (V_L of FIG. 2B) of the first vertical memory structure V1 may be transformed to be in the form of an ellipse having a major axis, as illustrated in FIG. 6. In the top view of FIG. 4B, the upper region V_UU of the upper vertical portion (V_U of FIG. 2B) of the first vertical memory structure V1 may be transformed to be in the form of an ellipse having a major axis as illustrated in FIG. 6. The major axis may have an orientation extending in the second direction Y.

In the top view of FIG. 4B, the upper region V_LU of the lower vertical portion (V_L of FIG. 2B) of the second vertical memory structure V2 may be transformed to be in the form of an ellipse having a major axis as shown in FIG. 6. In the top view of FIG. 4B, the upper region V_UU of the upper vertical portion (V_U of FIG. 2B) of the second vertical memory structure V2 may be transformed to be in the form of an ellipse having a major axis as illustrated in FIG. 6.

A maximum width of the upper region V_LU of the lower vertical portion (V_L of FIG. 2B) of the first vertical memory structure V1 may be greater than a maximum width of the upper region V_LU of the lower vertical portion (V_L of FIG. 2B) of the second vertical memory structure V2.

A maximum width of the upper region V_UU of the upper vertical portion (V_U of FIG. 2B) of the first vertical memory structure V1 may be greater than a maximum width of the upper region V_UU of the upper vertical portion (V_U of FIG. 2B) of the second vertical memory structure V2.

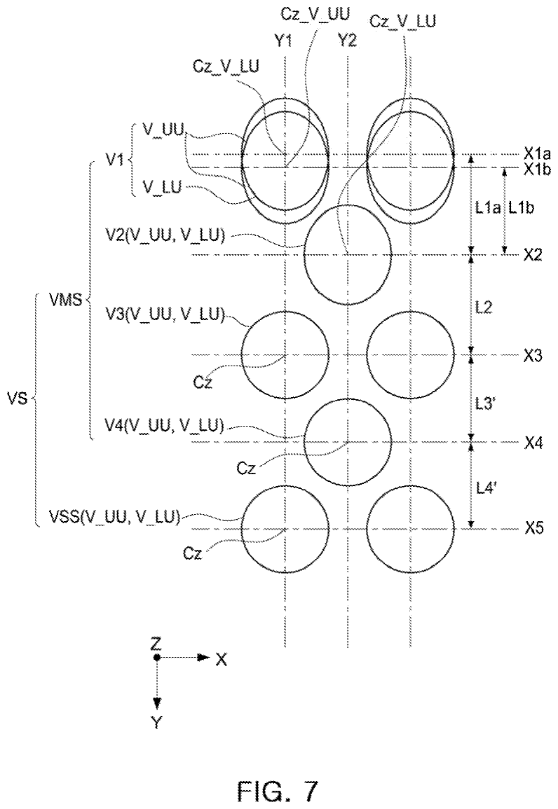

A modified example of the first distance L1a, the second distance L2, the third distance L3, and the fourth distance L4 described in FIGS. 3A to 3C will now be described with reference to FIG. 7.

The modified example of the first distance L1a, the second distance L2, the third distance L3, and the fourth distance L4 described in FIG. 7 may be equally applied to FIGS. 4A, 4B, 5A, 5B, and 6, as well as to FIG. 3A. For example, FIG. 7 illustrates a modified example of the third distance L3 and the fourth distance L4 illustrated in FIG. 5A in the top view of FIG. 5A, but may be equally applied to the top views of FIGS. 3A, 4A, 4B, 5B, and 6, as well as to the top view of FIG. 5A.

In the modified example, referring to FIG. 7, among the first distance L1a, the second distance L2, a third distance L3′, and a fourth distance L4′, one or a plurality of distances may have a size different from that of the remaining distances. For example, at least one of the third distance L3′ and the fourth distance L4′ may be smaller than the first distance L1a, and may be smaller than the second distance L2. For example, each of the third distance L3′ and the fourth distance L4′ may be smaller than the first distance L1a.

The first distance L1a and the second distance L2 may be substantially the same. The third distance L3′ and the fourth distance L4′ may be substantially the same.

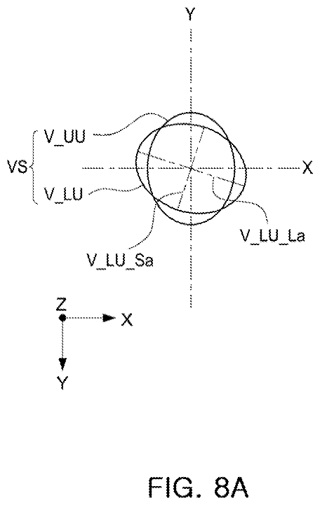

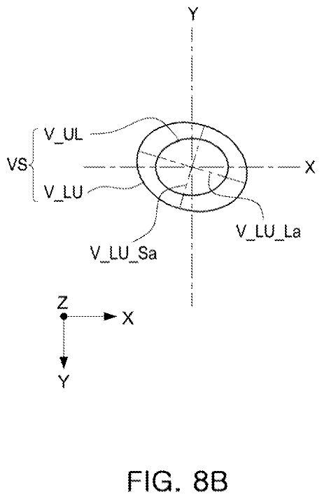

A modified example of at least one of the vertical structures VS will now be described with reference to FIGS. 8A and 8B.

For ease of description, among the vertical structures VS, one vertical structure VS may be mainly described.

FIG. 8A is a top view illustrating the upper region V_UU of the upper vertical portion (V_U of FIG. 2B) of the vertical structure VS and the upper region V_LU of the lower vertical portion (V_L of FIG. 2B).

FIG. 8B is a top view illustrating the upper region V_LU of the lower vertical portion (V_L of FIG. 2B) of the vertical structure VS and the lower region V_UL of the upper vertical portion (V_U of FIG. 2B).

In the modified example, referring to FIGS. 8A and 8B, in a top view, the upper region V_LU of the lower vertical portion (V_L of FIG. 2B) of the vertical structure VS may be in the form of an ellipse having a first major axis V_LU_La and a second minor axis V_LU_Sa. The upper region V_UU of the upper vertical portion (V_U of FIG. 2B) may be in the form of an ellipse having a second major axis, intersecting the first major axis V_LU_La, and a second minor axis, intersecting the first minor axis V_LU_Sa. The second major axis may extend in the second direction Y. The second minor axis may extend in the first direction X. The first major axis V_LU_La and the second major axis may form an acute angle.

In the top view, the lower region (V_UL of FIG. 8B) of the upper vertical portion (V_U of FIG. 2B) of the vertical structure VS may be in the form of an ellipse having a third major axis and a third minor axis. The third major axis may extend in the first direction X. The third minor axis may extend in the second direction Y. The third major axis may be substantially perpendicular to the second major axis.

In an example embodiment, a shape the same as a shape of the vertical structure VS as in FIGS. 8A and 8B or a shape similar to a shape of the vertical structure VS as in FIGS. 8A and 8B may be applied to one or a plurality of structures, among the first to third vertical memory structures V1, V2, and V3 described with reference to FIGS. 3A to 7.

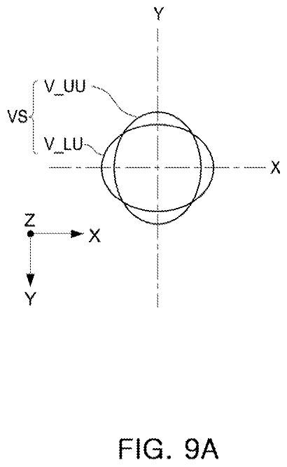

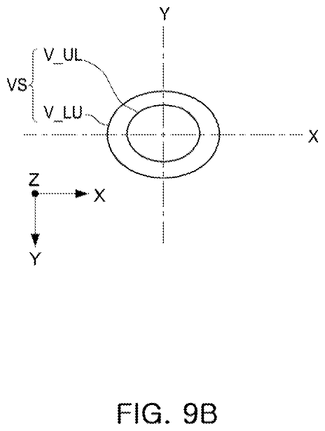

A modified example of at least one of the vertical structures VS will now be described with reference to FIGS. 9A and 9B.

For ease of description, among the vertical structures VS, one vertical structure VS will be mainly described.

FIG. 9A is a top view illustrating the upper region V_UU of the upper vertical portion (V_U of FIG. 2B) of the vertical structure VS and the upper region V_LU of the lower vertical portion (V_L of FIG. 2B).

FIG. 9B is a top view illustrating the upper region V_LU of the lower vertical portion (V_L of FIG. 2B) of the vertical structure VS and the lower region V_UL of the upper vertical portion (V_U in FIG. 2B).

In the modified example, referring to FIGS. 9A and 9B, in a top view, the upper region V_LU of the lower vertical portion (V_L of FIG. 2B) of the vertical structure VS be in the form of an ellipse having a first major axis and a first minor axis. The upper region V_UU of the upper vertical portion (V_U of FIG. 2B) may be in the form of an ellipse having a second major axis, substantially perpendicular to the first major axis, and a second minor axis, substantially perpendicular to the first minor axis. The first major axis may extend in the first direction X. The first minor axis may extend in the second direction Y. The second major axis may extend in the second direction Y. The second minor axis may extend in the first direction X.

In the top view, the lower region (V_UL of FIG. 9B) of the upper vertical portion (V_U of FIG. 2B) of the vertical structure VS may be in the form of an ellipse having a third major axis and a third minor axis. The third major axis may extend in the first direction X. The third minor axis may extend in the second direction Y.

Each of the first major axis and the third major axis may be substantially perpendicular to the second major axis.

In an example embodiment, a shape the same as a shape of the vertical structure VS as in FIGS. 9A and 9B or a shape similar to a shape of the vertical structure VS as in FIGS. 9A and 9B may be applied to one or a plurality of structures, among the first to third vertical memory structures V1, V2, and V3 described with reference to FIGS. 3A to 7.

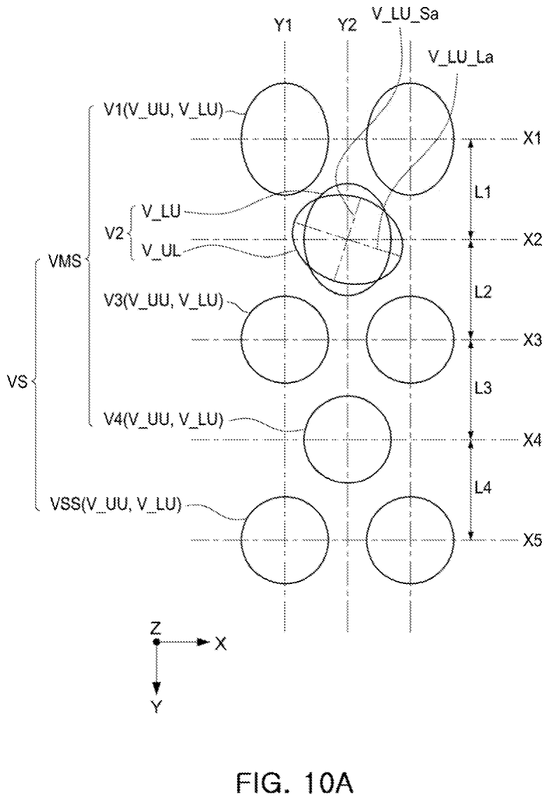

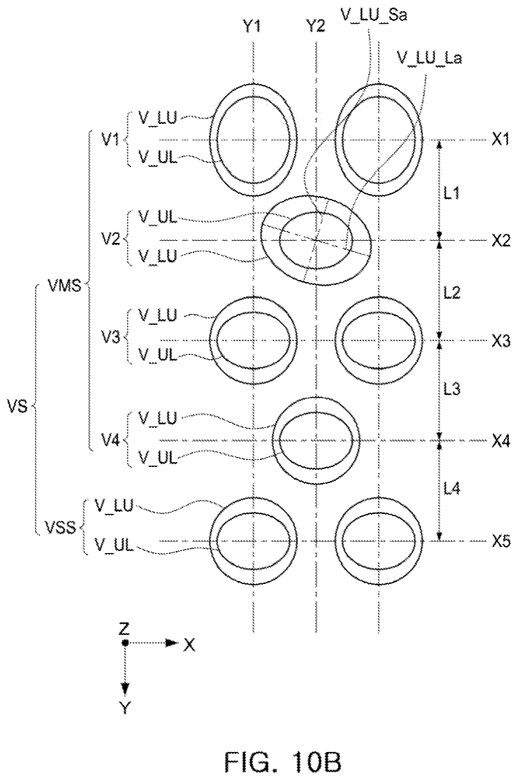

A modified example of applying a shape the same as a shape of the vertical structure VS as in FIGS. 8A and 8B to the first vertical memory structure V1, among the vertical structures VS of FIGS. 1A, 1B, 2A, and 2B, will now be described with reference to FIGS. 10A and 10B.

FIG. 10A is a top view illustrating the upper region V_LU of the lower vertical portion (V_L of FIG. 2B) and the upper region V_UU of the upper vertical portion (V_U of FIG. 2B) of each of the first to fourth vertical memory structures V1, V2, V3, and V4 and the vertical support structure VSS.

FIG. 10B is a top view illustrating the upper region V_LU of the lower vertical portion (V_L of FIG. 2B) and the lower region V_UL of the upper vertical portion (V_U of FIG. 2B) of each of the first to fourth vertical memory structures V1, V2, V3, and V4 and the vertical support structure VSS.

In the modified example, referring to FIGS. 10A and 10B, in a top view, the upper region V_LU of the lower vertical portion (V_L of FIG. 2B) of each of the first, third and fourth vertical memory structures V1, V3, and V4 and the vertical support structure VSS and the upper region V_UU of the upper vertical portion (V_U of FIG. 2B) of each of the first, third and fourth vertical memory structures V1, V3, and V4 and the vertical support structure VSS may match each other in a layout formed using a CAD program in a computer system before performing a semiconductor process, and may match each other within an allowable process error range after performing a semiconductor process such as a photolithography process and an etching process using the layout. For example, in the top view, the upper region V_LU of the lower vertical portion (V_L of FIG. 2B) of the first vertical memory structure V1 and the upper region V_UU of the upper vertical portion (V_U of FIG. 2B) of the first vertical memory structure V1 may have substantially the same shape.

The upper region V_LU of the lower vertical portion (V_L of FIG. 2B) of the first vertical memory structure V1 and the upper region V_UU of the upper vertical portion (V_U of FIG. 2B) of the first vertical memory structure V1 may each be in the form of an ellipse having a major axis and a minor axis. The major axis may be a direction extending in the second direction Y.

The second vertical memory structure V2 may have the same shape as the vertical structure VS described in FIGS. 8A and 8B, or may have the same shape as the vertical structure VS described in FIGS. 9A and 9B. For example, in the second vertical memory structure V2 as described with reference to FIGS. 8A and 8B, the upper region V_LU of the lower vertical portion (V_L of FIG. 2B) may be in the form of an ellipse having a first major axis V_LU_La and a first minor axis V_LU_Sa, the upper region V_UU of the upper vertical portion (V_U of FIG. 2B) may be in the form of an ellipse having a second major axis, intersecting the first major axis V_LU_La, and a second minor axis, intersecting the first minor axis V_LU_Sa, and the lower region (V_UL of FIG. 10B) of the upper vertical portion (V_U of FIG. 2B) may be in the form of an ellipse having a third major axis and a third minor axis.

The second major axis may extend in the second direction Y. The second minor axis may extend in the first direction X. The first major axis V_LU_La and the second major axis may form an acute angle, the third major axis may extend in the first direction X, and the third minor axis may extend in the second direction Y.

The lower region V_UL of the upper vertical portion (V_U in FIG. 2B) of each of the first, third, and fourth vertical memory structures V1, V3 and V4 and the vertical support structure VSS may be elliptical. A major-axis direction (e.g., the second direction Y) of the lower region V_UL of the upper vertical portion (V_U of FIG. 2B) of the first vertical memory structure V1 may be a direction intersecting a major-axis direction (e.g., the first direction X) of the lower region V_UL of the upper vertical portion (V_U of FIG. 2B) of at least one of the third and fourth vertical memory structures V3 and V4 and the vertical support structure VSS.

In the top view, there may be a first virtual horizontal axis X1 passing through the center of the upper region V_LU of the lower vertical portion (V_L of FIG. 2B) of the first vertical memory structure V1 and extending in the first direction X, a second virtual horizontal axis X2 passing through the center of the upper region V_LU of the lower vertical portion (V_L of FIG. 2B) of the second vertical memory structure V2 and extending in the first direction X, a third virtual horizontal axis X3 passing through the center of the upper region V_LU of the lower vertical portion (V_L of FIG. 2B) of the third vertical memory structure V3 and extending in the first direction X, a fourth virtual horizontal axis X4 passing through the center of the upper region V_LU of the lower vertical portion (V_L of FIG. 2B) of the fourth vertical memory structure V4 and extending in the first direction X, and a fifth virtual horizontal axis X5 passing through the center Cz of the upper region V_LU of the lower vertical portion (V_L of FIG. 2B) of the vertical support structure VSS) and extending in the first direction X.

A first distance L1 between the first virtual horizontal axis X1 and the second virtual horizontal axis X2, the second distance L2 between the second virtual horizontal axis X2 and the third virtual horizontal axis X3, the third distance L3 between the third virtual horizontal axis X3 and the fourth virtual horizontal axis X4, and a fourth distance L4 between the fourth virtual horizontal axis X4 and the fifth virtual horizontal axis X5 may be substantially the same.

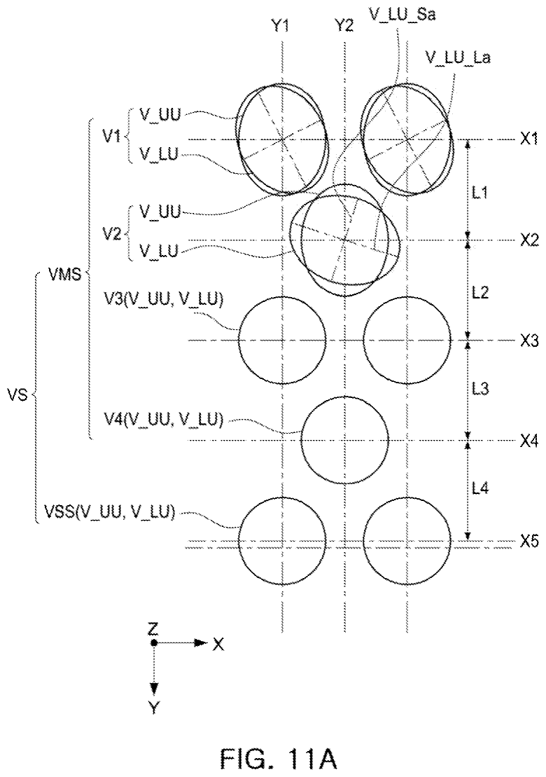

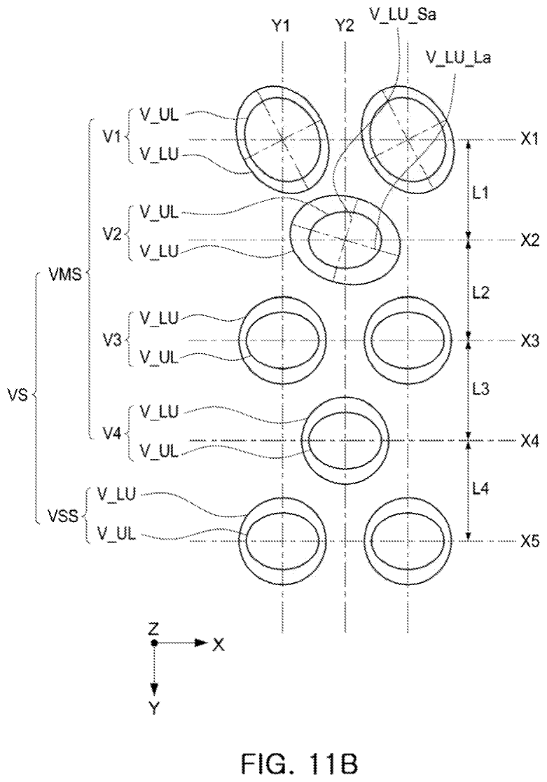

A modified example of applying a shape the same as or similar to a shape of the vertical structure VS as in FIGS. 8A and 8B to each of the first and second vertical memory structures V1 and V2, among the vertical structures VS of FIGS. 1A, 1B, 2A, and 2B, will now be described with reference to FIGS. 11A and 11B.

FIG. 11A is a top view illustrating the upper region V_LU of the lower vertical portion (V_L of FIG. 2B) and the upper region V_UU of the upper vertical portion (V_U of FIG. 2B) of each of the first to fourth vertical memory structures V1, V2, V3, and V4 and the vertical support structure VSS.

FIG. 11B is a top view illustrating the upper region V_LU of the lower vertical portion (V_L of FIG. 2B) and the lower region V_UL of the upper vertical portion (V_U of FIG. 2B) of each of the first to fourth vertical memory structures V1, V2, V3, and V4 and the vertical support structure VSS.

FIGS. 11A and 11B illustrate an example of applying a shape similar to a shape of the vertical structure VS of FIGS. 8A and 8B to the first vertical memory structure V1 in the top view of FIG. 10A, and FIG. 11B illustrate an example of applying a shape similar to a shape of the vertical structure VS of FIGS. 8A and 8B to the first vertical memory structure V1 in the top view of FIG. 10B.

In the modified example, the first vertical memory structure V1 of FIGS. 10A and 10B will be mainly described with reference to FIGS. 11A and 11B.

In the modified example, referring to FIGS. 11A and 11B, in a top view, the first vertical memory structure V1 may have a shape similar to a shape of the vertical structure VS as described with reference to FIGS. 8A and 8B. For example, in the first vertical memory structure V1 as described in FIGS. 8A and 8B, the upper region V_LU of the lower vertical portion (V_L of FIG. 2B) may be in the form of an ellipse having a major axis and a minor axis. The upper region V_UU of the upper vertical portion (V_U of FIG. 2B) may be in the form of an ellipse having a major axis and a minor axis. The lower region (V_U of FIG. 10B) of the upper vertical portion (V_U of FIG. 2B) V_UL) may be in the form of an ellipse having a major axis and a minor axis. A major-axis direction of the upper region V_LU of the lower vertical portion (V_L of FIG. 2B) of the first vertical memory structure V1 may be inclined to each of the second direction Y and the first direction X, and may have an orientation intersecting an major-axis direction of the upper region V_LU of the lower vertical portion (V_L of FIG. 2B) of the second vertical memory structure V2 as illustrated in FIG. 10A while forming an acute angle therewith. Similarly, a major-axis direction of the upper region V_UU of the upper vertical portion (V_U of FIG. 2B) of the first vertical memory structure V1 may have an orientation intersecting a major-axis direction of the upper region V_UU of the upper vertical portion (V_U of FIG. 2B) of the second vertical memory structure V2 as illustrated in FIG. 10A while forming an acute angle therewith.

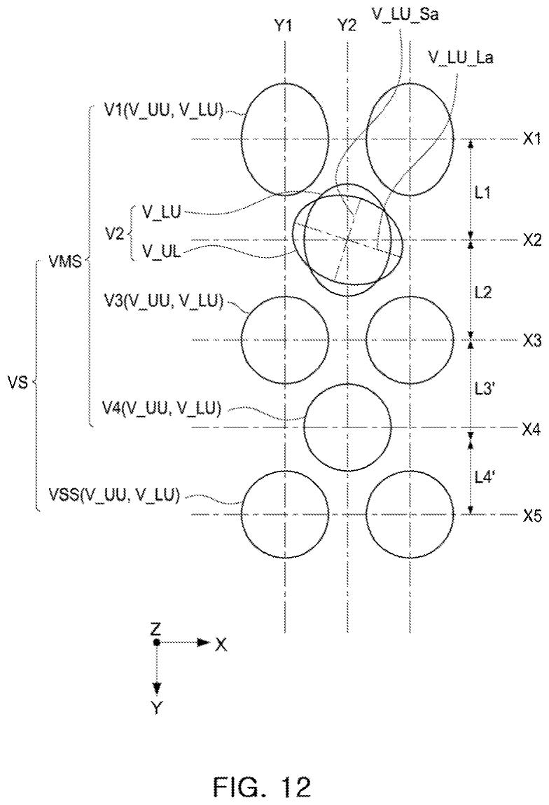

An example of changing the third distance L3 and the fourth distance L4 as described in FIGS. 3A to 3C into the third distance L3′ and the fourth distance L4′, relatively reduced as described in FIG. 7, will now be described with reference to FIG. 12.

In detail, a modified example of the first distance L1, the second distance L2, the third distance L3, and the fourth distance L4 described in FIGS. 10A and 10B will now be described with reference to FIG. 12.

The modified example of the first distance L1, the second distance L2, the third distance L3, and the fourth distance L4 in FIG. 12 may be equally applied to FIGS. 11A and 11B, as well as to FIGS. 10A and 10B. For example, FIG. 12 illustrates a modified example of the third distance L3 and the fourth distance L4 illustrated FIG. 10A, but may be equally applied to the top views of FIGS. 11A and 11B, as well as to the top view of FIG. 10A.

In the modified example, referring to FIG. 12, among the first distance L1, the second distance L2, the third distance L3, and the fourth distance L4, one or a plurality of distances may have a size different from a size of the remaining distance. For example, at least one of the third distance L3′ and the fourth distance L4′ may be smaller than the first distance L1, and may be smaller than the second distance L2. For example, each of the third distance L3′ and the fourth distance L4′ may be smaller than the first distance L1.

The first distance L1 and the second distance L2 may be substantially the same. The third distance L3′ and the fourth distance L4′ may be substantially the same.

In an example embodiment, a shape the same as or similar a shape of the vertical structure VS in FIGS. 8A and 8B may be applied to one or a plurality of vertical memory structures, among the first to third vertical memory structures V1, V2, and V3 described with reference to FIGS. 3A to 7.

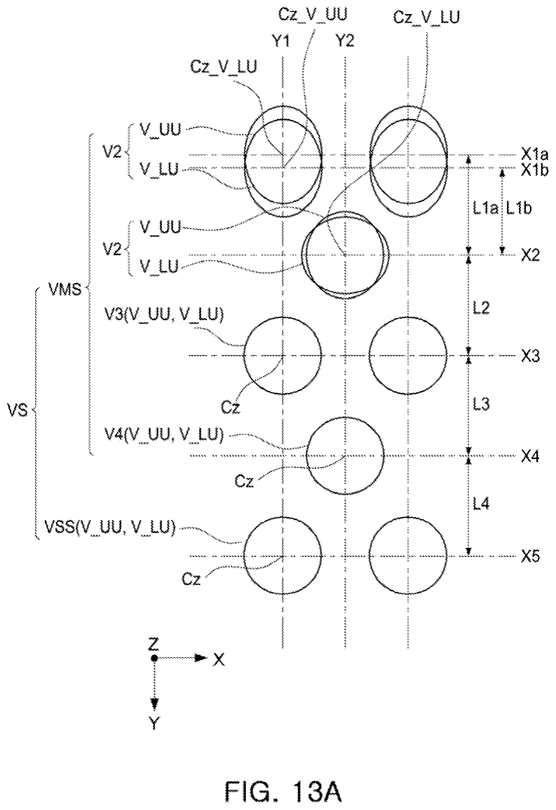

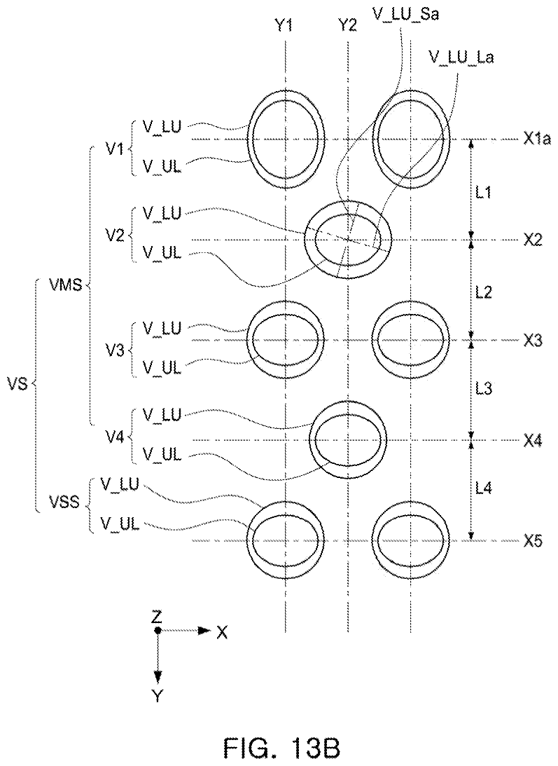

An example of applying a shape the same as or similar a shape of the vertical structure VS in FIGS. 8A and 8B to one or a plurality of vertical memory structures, among the first to third vertical memory structures V1, V2, and V3 described with reference to FIGS. 3A to 7, will now be described with reference to FIGS. 13A and 13B.

FIG. 13A illustrates an example in which the second vertical memory structure V2 is transformed like the vertical structure VS of FIG. 8A in the top view of FIG. 5A.

FIG. 13B illustrates an example in which the second vertical memory structure V2 is transformed like the vertical structure VS of FIG. 8B in the top view of FIG. 5B.

Referring to FIGS. 13A and 13B, the second vertical memory structure V2 may be transformed like the vertical structure VS of FIG. 8A in the top view of FIG. 5A, and the second vertical memory structure V2 may be deformed like the vertical structure VS of FIG. 8B in the top view of FIG. 5B. For example, in the second vertical structure VS2, the upper region V_LU of the lower vertical portion (V_L of FIG. 2B) may be in the form of an ellipse as illustrated in FIG. 8A, the upper region V_UU of the upper vertical portion (V_U of FIG. 2B) may be in the form of an ellipse as illustrated in FIG. 8A, and a lower region (V_UL of FIG. 13B) of the upper vertical portion (V_U of FIG. 2B) may be in the form of an ellipse as illustrated in FIG. 8B.

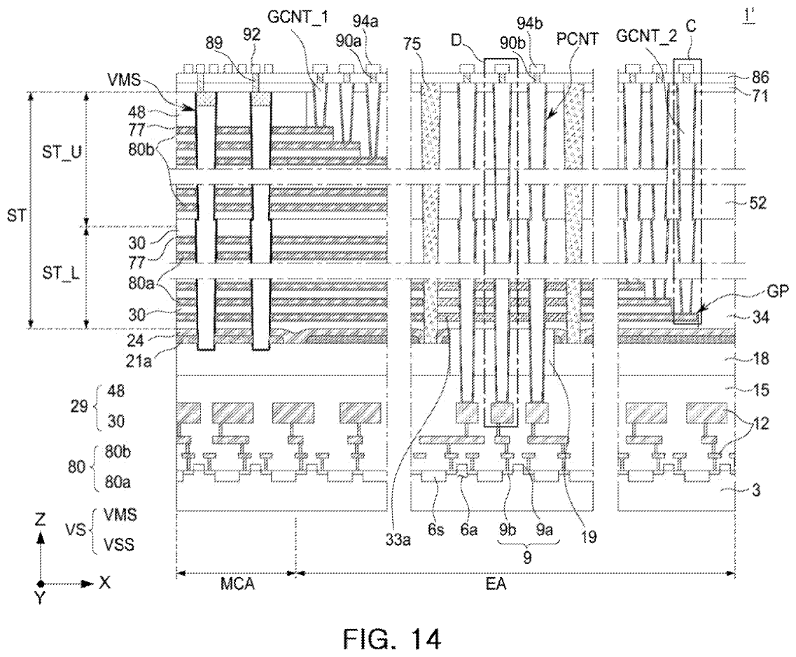

A modified example of a semiconductor device according to an example embodiment will now be described with reference to FIG. 14.

FIGS. 1A to 2B illustrate a semiconductor device 1 in a memory cell array region MCA. FIG. 14 illustrates a cross-sectional structure of a semiconductor device 1′ including the memory cell array region MCA and an extension region EA on one side of the memory cell array region MCA. In FIG. 14, the memory cell array region MCA may represent a cross-sectional structure obtained by cutting a region including at least some of the vertical memory structures VMS in the first direction X.

In the modified example, referring to FIG. 14, the semiconductor device 1′ may include the semiconductor substrate 3 substantially the same as described with reference to FIGS. 1A to 2B, the peripheral circuit 9 on the semiconductor substrate 3, the peripheral interconnection 12 electrically connected to the peripheral circuit 9 on the semiconductor substrate 3, and a lower insulating layer 15 covering the peripheral circuit 9 and the peripheral interconnection 12 on the semiconductor substrate 3.

In the semiconductor device 1′, the base 18 described with reference to FIGS. 1A to 2B may extend inwardly of the extension region EA from the memory cell array region MCA.

The semiconductor device 1′ may further include a lower dummy layer 21b spaced apart from the lower horizontal layer 21a on the base 18 in the extension region EA. The lower dummy layer 21b may include at least one insulating layer. The lower dummy layer 21b may include a silicon oxide layer, a silicon nitride layer, and a silicon oxide layer sequentially stacked. The upper horizontal layer 24 may extend between the lower horizontal layer 21a and the lower dummy layer 21b to contact the base 18.

The semiconductor device 1′ may further include an intermediate insulating layer 19 penetrating through the upper horizontal layer 24, the lower dummy layer 21b, and the base 18 in the extension region EA. The intermediate insulating layer 19 may penetrate through a portion of the base 18.

In the semiconductor device 1′, the stack structure ST described with reference to FIGS. 1A to 2B may extend inwardly of the extension region EA to have a staircase shape in the extension region EA. For example, the gate electrodes 80 of the stack structure ST may extend inwardly of the extension region EA from the memory cell array region MCA, and may include gate pads GP arranged in a staircase shape in the extension region EA.

The semiconductor device 1′ may further include a lower capping insulating layer 34, covering the first stack region ST_L of the stack structure ST in the extension region EA, and an upper capping insulating layer 52 covering the second stack region ST_L of the stack structure ST and the lower capping insulating layer 34.

A portion of the stack structure ST may be a through-region. For example, a portion of the stack structure ST, which may be a through region, may further include dummy insulating layers 33a on the same height level as the gate electrodes 80.

In the semiconductor device 1′, the separation structures 83 of FIG. 1 may extend from the memory cell array region MCA to cross the extension region EA.

In the semiconductor device 1′, the first and second upper insulating layers 71 and 86 may extend inwardly of the extension region EA from the memory cell array region MCA.

The semiconductor device 1′ may further include a dam structure 75 penetrating through the stack structure ST in the extension region EA and penetrating through the lower and upper capping insulating layers 34 and 52 and the first upper insulating layer 71. The dam structure 75 may be disposed between separation structures (83 of FIG. 1) and may be spaced apart from the separation structures (83 of FIG. 1). Accordingly, among the gate electrodes 80, gate electrodes adjacent to the dam structure 75 may include a portion disposed between the dam structure 75 and the separation structures (83 of FIG. 1).

The semiconductor device 1′ may further include gate contact plugs GCNT_1 and GCNT_2 in contact with the gate pads GP of the gate electrodes 80. The gate contact plugs GCNT_1 and GCNT_2 may further include lower gate contact plugs GCNT_1 in contact with gate pads of the lower gate electrodes 80a of the first stack region ST_L and upper gate contact plugs GCNT_2 in contact with the gate pads GP of the upper gate electrodes 80b of and the second stack region ST_U.

The semiconductor device 1′ may further include peripheral contact plugs PCNT extending downwardly through the first upper insulating layer 71, a region of the stack structure ST defined by the lower and upper capping insulating layers 34 and 52 and the dam structure 75, and the intermediate insulating layer 19 and electrically connected to the peripheral interconnection 12.

The semiconductor device 1′ may further include first contact plugs 90a penetrating through the second upper insulating layer 86 and electrically connected to the gate contact plugs GCNT_1 and GCNT_2, second contact plugs 90b penetrating through the second upper insulating layer 86 and electrically connected to the peripheral contact plugs PCNT, first interconnections 94a electrically connected to the first contact plugs 90a on the second upper insulating layer 86, and second interconnections 94b electrically connected to the second contact plugs 90b on the second upper insulating layer 86.

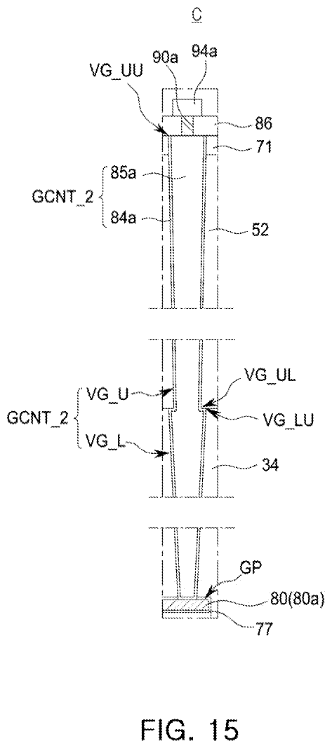

A cross-sectional structure of the lower gate contact plugs GCNT_2 will now be described with reference to FIGS. 14 and 15.

FIG. 15 is a partially enlarged view of region “C” of FIG. 14.

Referring to FIGS. 14 and 15, each of the lower gate contact plugs GCNT_2 may include a plug portion 85a and a liner layer 54a covering a side surface and a bottom surface of the plug portion 85a. The plug portion 85a may include a metal such as tungsten. The liner layer 54a may include a metal nitride such as titanium nitride (TiN).

Each of the lower gate contact plugs GCNT_2 may include a gate lower vertical portion VG_L, on a level higher than a level of the second stack region ST_U, and a gate upper vertical portion VG U on a level higher than a level of the first stack region ST_L and extending from the gate lower vertical portion VG_L. An upper region VG_LU of the gate lower vertical portion VG_L and a lower region VG_UL of the gate upper vertical portion VG U may be coplanar with an upper surface of the lower capping insulating layer 34 and an upper surface of the first stack region ST_L. An upper region VG_UU of the gate upper vertical portion VG U may be coplanar with an upper surface of the first upper insulating layer 71.

A width of the upper region VG_LU of the lower vertical portion VG_L may be greater than a width of the lower region VG_UL of the gate upper vertical portion VG U. A width of the upper region VG_UU of the gate upper vertical portion VG U may be greater than a width of the lower region VG_UL of the gate upper vertical portion VG U.

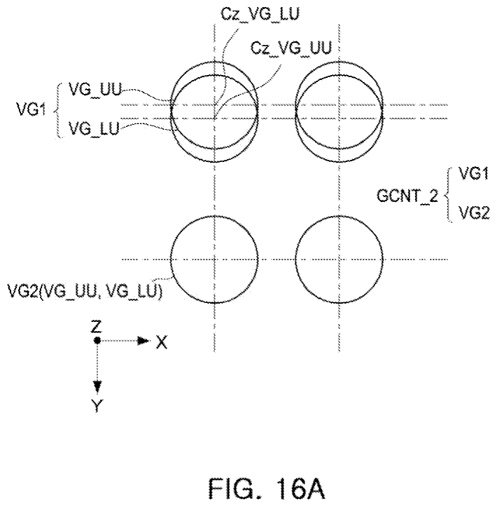

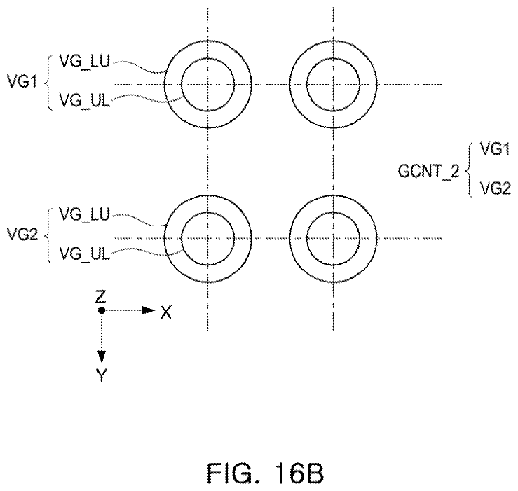

The lower gate contact plugs GCNT_2 may include a first gate contact plug (VG1 of FIGS. 16A and 16B), on an external side in a region in which the gate contact plugs GCNT_1 and GCNT_2 are concentrated, and a second gate contact plug (VG2 of FIGS. 16A and 16B) on an internal side in the region in which the gate contact plugs GCNT_1 and GCNT_2 are concentrated.

A top view of the upper region VG_LU of the lower gate vertical portion (VG_L of FIG. 15), the lower region VG_UL of the gate upper vertical portion (V_U of FIG. 15), and the upper region VG_UU of the gate upper vertical portion (VG U of FIG. 15) in the first and second gate contact plugs VG1 and VG2 will now be described with reference to FIGS. 16A and 16B together with FIG. 15.

FIG. 16A is a top view illustrating an upper region VG_LU of the gate lower vertical portion (VG_L of FIG. 15) and an upper region VG_UU of the gate upper vertical portion (VG U of FIG. 15) of each of the first and second gate contact plugs VG1 and VG2.

FIG. 16B is a top view illustrating an upper region VG_LU of the gate lower vertical portion (VG_L of FIG. 15) and a lower region VG_UL of the gate upper vertical portion (VG U of FIG. 15) of each of the first and second gate contact plugs VG1 and VG2.

Referring to FIGS. 16A and 16B together with FIG. 15, in a top view, a first center Cz_VG_LU of the upper region VG_LU of the gate lower vertical portion (VG_L of FIG. 15) of the first gate contact plug VG1 and a second center Cz_VG_UU of the upper region VG_UU of the gate upper vertical portion (VG U in FIG. 15) of the first gate contact plug VG1 may be spaced apart from each other. A distance between the first center Cz_VG_LU and the second center Cz_VG_UU may be a distance in a layout formed using a CAD program in a computer system before performing a semiconductor process.

The distance between the first center Cz_VG_LU and the second center Cz_VG_UU may include a distance in a layout formed using a CAD program in a computer system before performing a semiconductor process and a distance caused by an allowable process error range after performing semiconductor processes such as a photolithography process and an etching process.

In the top view, a center of the upper region VG_LU of the gate lower vertical portion (VG_L of FIG. 15) of the second gate contact plug VG2 and a center of the upper region VG_UU of the gate upper vertical portion (VG U of FIG. 15) of the second gate contact plug VG2 may overlap each other. The center of the upper region VG_LU of the gate lower vertical portion (VG_L of FIG. 15) of the second gate contact plug VG2 and the center of the upper region VG_UU of the gate upper vertical portion (VG U of FIG. 15) of the second gate contact plug VG2 may match each other in a layout formed using a CAD program in a computer system before performing a semiconductor process.

A center Cz of the upper region VG_LU of the gate lower vertical portion (VG_L of FIG. 15) of the second gate contact plug VG2 and a center of the upper region VG_UU of the gate upper vertical portion (VG U of FIG. 15) of the second gate contact plug VG2 may be spaced apart from each other within an allowable process error range after performing semiconductor processes such as a photolithography process and an etching process.

Accordingly, in the top view, a distance the first center Cz_VG_LU of the upper region VG_LU of the gate lower vertical portion (VG_L of FIG. 15) of the first gate contact plug VG1 and the second center Cz_VG_UU of the upper region VG_UU of the gate upper vertical portion (VG U in FIG. 15) of the first gate contact plug VG1 may be greater than a distance between the center Cz of the upper region VG_LU of the gate lower vertical portion (VG_L of FIG. 15) of the second gate contact plug VG2 and the center of the upper region VG_UU of the gate upper vertical portion (VG U of FIG. 15) of the second gate contact plug VG2.

In the top view, the lower region VG_UL of the gate upper vertical portion (VG U in FIG. 15) of each of the first and second gate contact plugs VG1 and VG2 may be in the upper region VG_LU of the gate lower vertical portion (VG_L of FIG. 15) of each of the first and second gate contact plugs VG1 and VG2.

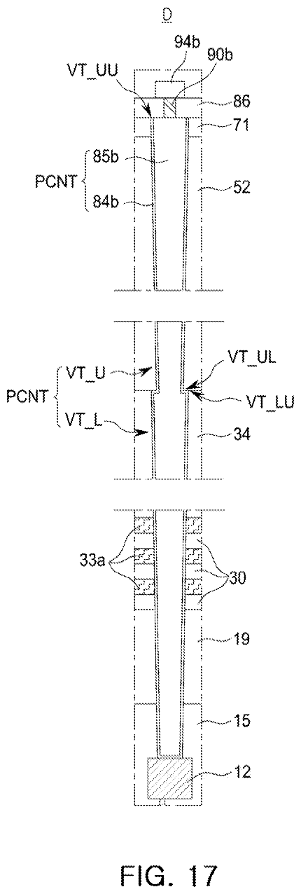

A cross-sectional structure of the peripheral contact plugs PCNT will now be described with reference to FIGS. 14 and 17.

FIG. 17 is a partially enlarged view of region “D” of FIG. 14.

Referring to FIGS. 14 and 17, each of the peripheral contact plugs PCNT may include a plug portion 85b and a liner layer 54b covering a side surfaces and a bottom surface of the plug portion 85b. The plug portion 85b may include a metal such as tungsten. The liner layer 54b may include a metal nitride such as titanium nitride (TiN).

Each of the peripheral contact plugs PCNT may include a peripheral lower vertical portion VT_L, on a level lower than a level of the second stack region ST_U, and a peripheral upper vertical portion VT_U on a level higher than a level of the first stack region ST_L and extending from the peripheral lower vertical portion VT_L. An upper region VT_LU of the peripheral lower vertical portion VT_L and a lower region VT_UL of the peripheral upper vertical portion VT_U may be coplanar with an upper surface of the lower capping insulating layer 34 and an upper surface of the first stack region ST_L. An upper region VT_UU of the peripheral upper vertical portion VT_U may be coplanar with an upper surface of the first upper insulating layer 71.

A width of the upper region VT_LU of the peripheral lower vertical portion VT_L may be greater than a width of the lower region VT_UL of the peripheral upper vertical portion VT_U. A width of the upper region VT_UU of the peripheral upper vertical portion VT_U may be greater than a width of the lower region VT_UL of the peripheral upper vertical portion VT_U.

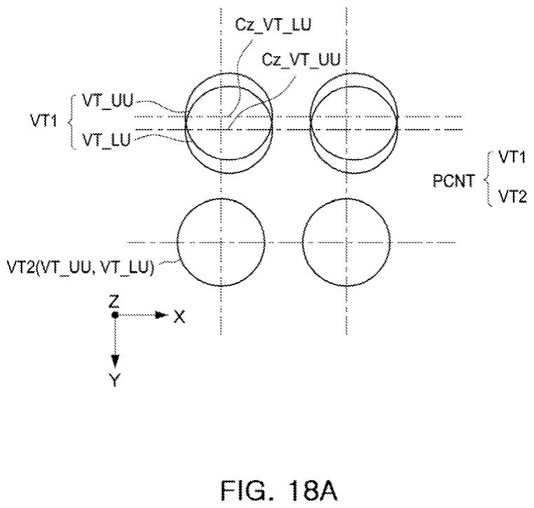

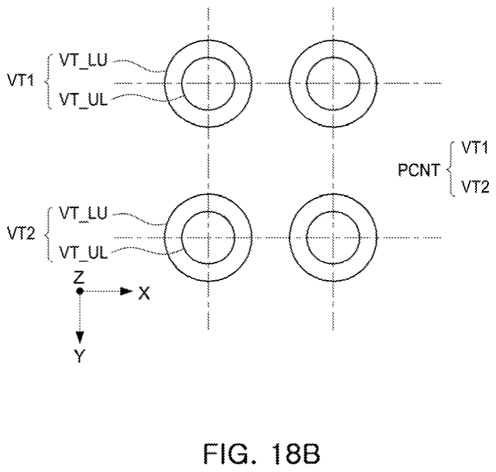

The peripheral contact plugs PCNT may include a first peripheral contact plug (VT1 of FIGS. 18A and 18B), on an external side in a region in which the peripheral contact plugs PCNT are concentrated, and a second peripheral contact plug (VT2 of FIGS. 18A and 18B) on an internal side in a region in which the peripheral contact plugs PCNT are concentrated.

A top view of the upper region VT_LU of the peripheral lower vertical portion (VT_L of FIG. 17), the lower region VT_UL of the peripheral upper vertical portion (V_U of FIG. 17), and the upper region VT_UU of the peripheral upper vertical portion (VT_U in FIG. 17) in the first and second peripheral contact plugs VT1 and VT2 will now be described with reference to FIGS. 18A and 18B together with FIG. 17.

FIG. 18A is a top view illustrating the upper region VT_LU of the peripheral lower vertical portion (VT_L of FIG. 17) and the upper region VT_UU of the peripheral upper vertical portion (VT_U of FIG. 17) of each of the first and second peripheral contact plugs VT1 and VT2.

FIG. 18B is a top view illustrating the upper region VT_LU of the peripheral lower vertical portion (VT_L of FIG. 17) and the lower region VT_UL of the peripheral upper vertical part (VT_U of FIG. 17) of each of the first and second peripheral contact plugs VT1 and VT2.

Referring to FIGS. 18A and 18B together with FIG. 15, in a top view, a first center Cz_VT_LU of the upper region VT_LU of the peripheral lower vertical portion (VT_L of FIG. 17) of the first peripheral contact plug VT1 and a second center Cz_VT_UU of the upper region VT_UU of the peripheral upper vertical portion (VT_U of FIG. 17) of the first peripheral contact plug VT1 may be spaced apart from each other. A distance between the first center Cz_VT_LU and the second center Cz_VT_UU may be a distance in a layout formed using a CAD program in a computer system before performing a semiconductor process.

The distance between the first center Cz_VT_LU and the second center Cz_VT_UU may include a distance in a layout formed using a CAD program in a computer system before performing a semiconductor process and a distance caused by an allowable process error range after performing semiconductor processes such as a photolithography process and an etching process.

In the top view, a center of the upper region VT_LU of the peripheral lower vertical portion (VT_L of FIG. 17) of the second peripheral contact plug VT2 and a center of the upper region VT_UU of the peripheral upper vertical portion (VT_U of FIG. 17) of the second peripheral contact plug VT2 may overlap each other. The center of the upper region VT_LU of the peripheral lower vertical portion (VT_L of FIG. 17) of the second peripheral contact plug VT2 and the center of the upper region VT_UU of the peripheral upper vertical portion (VT_U of FIG. 17) of the second peripheral contact plug VT2 may match each other in a layout formed using a CAD program in a computer system before performing a semiconductor process.

A center Cz of the upper region VT_LU of the peripheral lower vertical portion (VT_L of FIG. 17) of the second peripheral contact plug VT2 and a center of the upper region VT_UU of the peripheral upper vertical portion (VT_U of FIG. 17) of the second peripheral contact plug VT2 may be spaced apart from each other within an allowable process error range after performing semiconductor processes such as a photolithography process and an etching process.

Accordingly, in the top view, a distance between the first center Cz_VT_LU of the upper region VT_LU of the peripheral lower vertical portion (VT_L of FIG. 17) of the first peripheral contact plug VT1 and the second center Cz_VT_UU of the upper region VT_UU of the peripheral upper vertical portion (VT_U of FIG. 17) of the first peripheral contact plug VT1 may be greater than a distance between the center of the upper region VT_LU of the peripheral lower vertical portion (VT_L of FIG. 17) of the second peripheral contact plug VT2 and the center of the upper region VT_UU of the peripheral upper vertical portion (VT_U of FIG. 17) of the second peripheral contact plug VT2.

In the top view, the lower region VT_UL of the peripheral upper vertical portion (VT_U of FIG. 17) of each of the first and second peripheral contact plugs VT1 and VT2 may be in the upper region VT_LU of the peripheral lower vertical portion (VT_L of FIG. 17) of each of the first and second peripheral contact plugs VT1 and VT2.

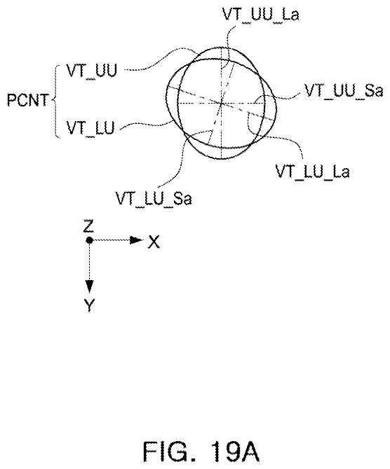

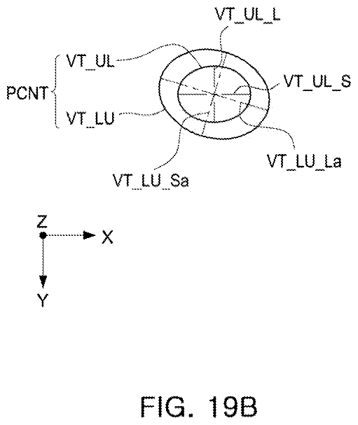

A modified example of at least one of the peripheral contact plugs PCNT will now be described with reference to FIGS. 19A and 19B.

For ease of description, the peripheral contact structure PCNT of one of the peripheral contact plugs PCNT will be mainly described.

FIG. 19A is a top view illustrating an upper region VT_UU of the peripheral upper vertical portion (VT_U of FIG. 17) of the peripheral contact structure PCNT and the upper region VT_LU of the peripheral lower vertical portion (VT_L of FIG. 17).

FIG. 19B is a top view illustrating an upper region VT_LU of the peripheral lower vertical portion (VT_L in FIG. 17) of the peripheral contact structure PCNT and a lower region VT_UL of the peripheral upper vertical portion (VT_U of FIG. 17).

In the modified example, referring to FIGS. 19A and 19B, in a top view, the upper region VT_LU of the peripheral lower vertical portion (V_L of FIG. 17) of the peripheral contact structure PCNT may be in the form of an ellipse having a first major axis VT_LU_La and a first minor axis VT_LU_Sa. The upper region VT_UU of the peripheral upper vertical portion (VT_U of FIG. 17) may be in the form of an ellipse having a second major axis VT_UU_La, intersecting the first major axis VT_LU_La, and a second minor axis VT_UU Sa intersecting the first minor axis VT_LU_Sa.

In the top view, the lower region (VT_UL of FIG. 19B) of the upper vertical portion (V_U of FIG. 17) of the peripheral contact structure PCNT may be in the form of an ellipse having a third major axis VT_UL_L and a third minor axis VT_UL_S.

The first major axis VT_LU_La, the second major axis VT_UU_La, and the third major axis VT_UL_L may have orientations extending in different directions.

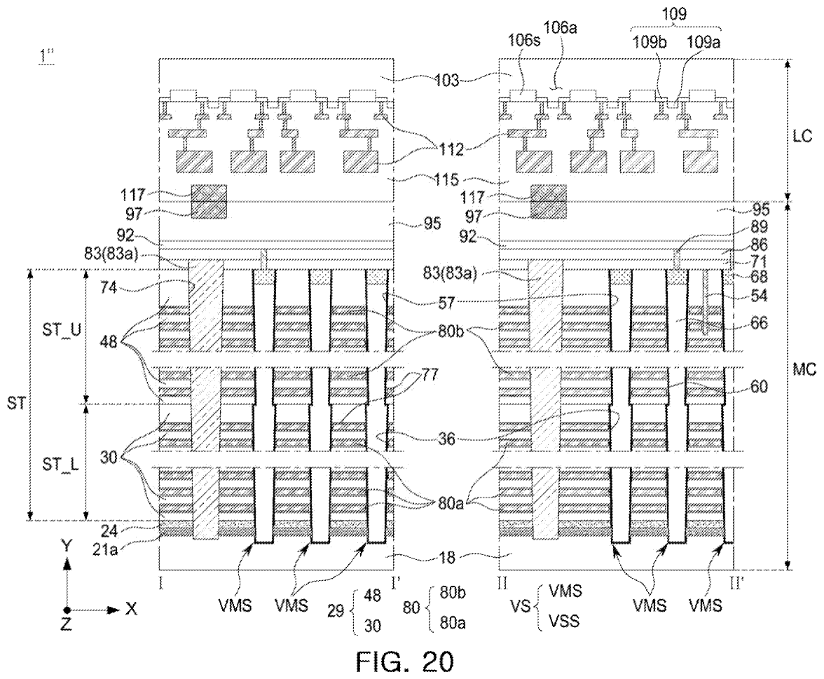

A modified example of a semiconductor device according to an example embodiment will now be described with reference to FIG. 20.

FIG. 20 is a schematic cross-sectional view illustrating a region taken along line I-I′ and a region taken along line II-II′ of FIG. 1B to describe a modified example of a semiconductor device according to an example embodiment.

In the modified example, referring to FIG. 20, a semiconductor device 1″ may include a lower semiconductor chip MC and an upper semiconductor chip LC. The lower semiconductor chip MC may be a memory semiconductor chip. The upper semiconductor chip LC may be a logic semiconductor chip or a controller semiconductor chip.

The lower semiconductor chip MC may include the base 10, the lower and upper horizontal layers 21a and 24, the stack structure ST, the vertical structures VS, the separation structures 83, the bitline contact plugs 89, and the bitlines 92 as described with reference to FIGS. 1A to 2B. The lower semiconductor chip MC may further include an upper insulating layer 95, covering the bitlines BL on the stack structure ST, and lower bonding pads 97 buried in the upper insulating layer 95 and coplanar with an upper surface of the upper insulating layer 95.

The upper semiconductor chip LC may include a semiconductor substrate 103, a peripheral circuit 109 on the semiconductor substrate 103, a peripheral interconnection 112 electrically connected to the peripheral circuit 109 on the semiconductor substrate 103, a lower insulating layer 115 covering the peripheral circuit 109 and the peripheral interconnection 112 on the semiconductor substrate 103, and upper bonding pads 117 buried in the lower insulating layer 115 and coplanar with an upper surface of the lower insulating layer 115. The peripheral circuit 109 may include a transistor including a gate 109a and source/drain regions 109b. The source/drain regions 109b may be in an active region 106a defined by an isolation region 106s on the semiconductor substrate 103. The gate 109a may be on the active region 106a between the source/drain regions 109b.

The lower insulating layer 115 and the upper bonding pads 117 of the upper semiconductor chip LC may be bonded to each other while being respectively in contact with the upper insulating layer 95 and the lower bonding pads 97 of the lower semiconductor chip MC. The upper bonding pads 117 and the lower bonding pads 97 may include the same metal material, e.g., copper.

The vertical structures VS of the lower semiconductor chip MC may have various shapes as described with reference to FIGS. 3A to 13B.

The lower semiconductor chip MC may further include the same gate contact plugs GCNT_1 and GCNT_2 as described with reference to FIGS. 14 to 16B.

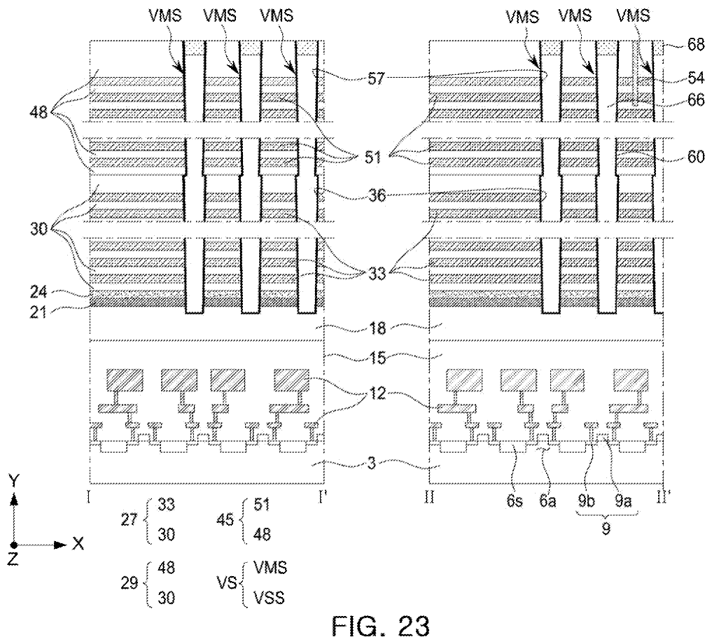

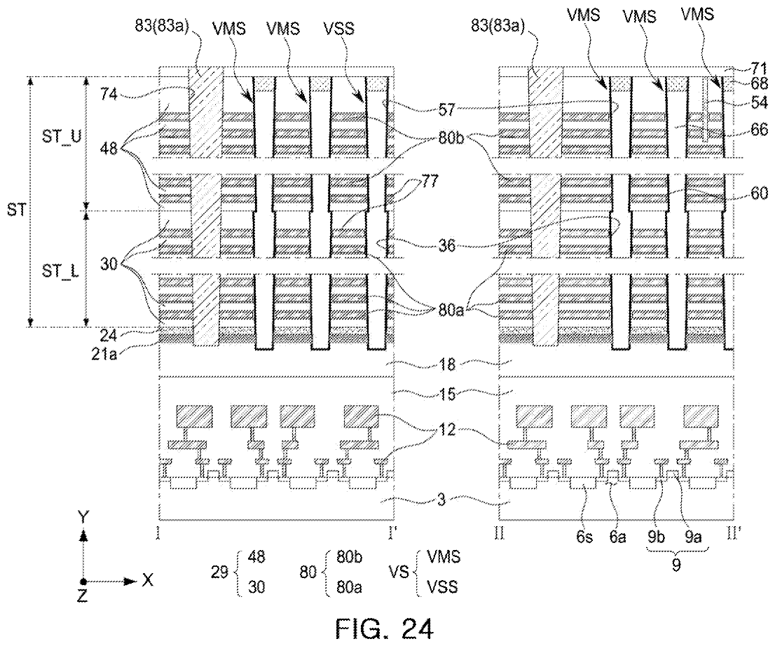

An example of a method of forming a semiconductor device according to an example embodiment will now be described with reference to FIGS. 1A and 1B and FIGS. 21 to 25.

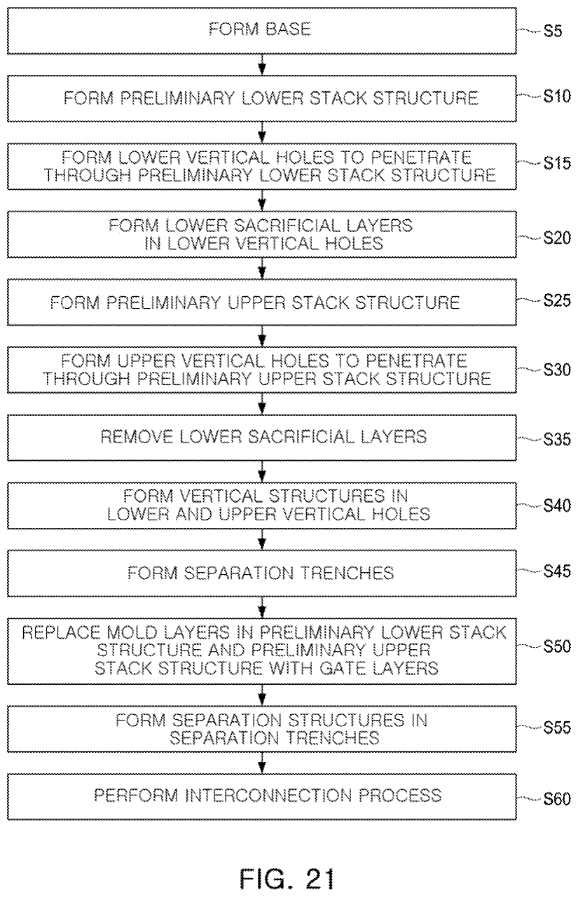

FIG. 21 is a schematic process flowchart illustrating an example of a method of forming a semiconductor device according to an example embodiment.

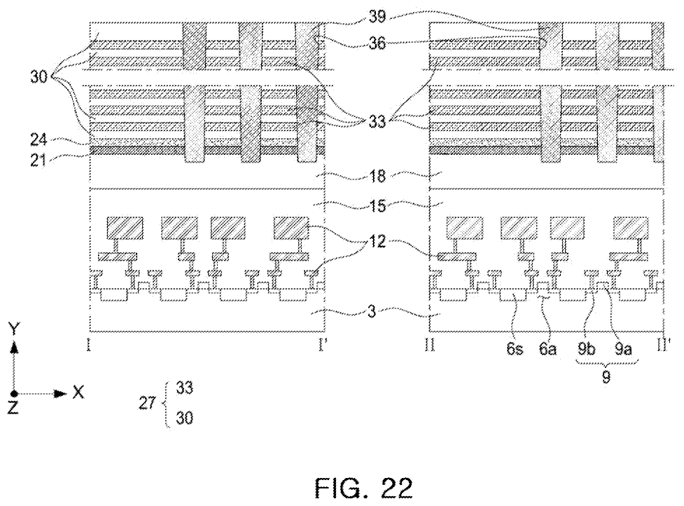

FIGS. 22 to 25 are schematic cross-sectional views illustrating a region taken along line I-I′ and a region taken along line II-II′ of FIG. 1 in FIG. 1B to describe an example of a method of forming a semiconductor device.

Referring to FIGS. 1A, 1B, 21, and 22, a semiconductor substrate 3 may be prepared. A peripheral circuit 9 may be formed on the semiconductor substrate 3. The peripheral circuit 9 may include a transistor including a gate 9a and source/drain regions 9b. The source/drain regions 9b may be formed in an active region 6a defined by an isolation region 6s on the semiconductor substrate 3. The gate 9a may be formed on the active region 6a.

A peripheral interconnection 12, electrically connected to the peripheral circuit 9, and a lower insulating layer 15, covering the peripheral interconnection 12, may be formed on the semiconductor substrate 3.

In operation S5, a base 18 may be formed. The base 18 may include at least a silicon layer. For example, the base 18 may include a polysilicon layer having N-type conductivity.

A lower horizontal layer 21 and an upper horizontal layer 24 may be sequentially formed on the base 18. The lower horizontal layer 21 may include an oxide, a nitride, and an oxide sequentially stacked. The upper horizontal layer 24 may include a silicon layer.

In operation S10, a preliminary lower stack structure 27 may be formed. The preliminary lower stack structure 27 may include lower interlayer insulating layers 30 and lower mold layers 33 alternately stacked. Among the lower interlayer insulating layers 30 and the lower mold layers 33, a lowermost layer may be a lowermost lower interlayer insulating layer, and an uppermost layer may be an uppermost lower interlayer insulating layer. The lower interlayer insulating layers 30 may be formed of silicon oxide. The lower mold layers 33 may be formed of silicon nitride or silicon.

In operation S15, lower vertical holes 36 may be formed to penetrate through the preliminary lower stack structure 27. The lower vertical holes 36 may penetrate through the lower and upper horizontal layers 21 and 24, and may extend inwardly of the base 18.

The lower vertical holes 36 may be formed using a first photolithography process and a first etching process.

In operation S20, lower sacrificial layers 39 may be formed in the lower vertical holes 36.

Referring to FIGS. 1A, 1B, 21, and 23, in operation S25, a preliminary upper stack structure 45 may be formed. The preliminary upper stack structure 45 may include upper interlayer insulating layers 48 and upper mold layers 51 alternately stacked. Among the upper interlayer insulating layers 48 and the upper mold layers 51, a lowermost layer may be a lowermost upper interlayer insulating layer, and an uppermost layer may be an uppermost upper interlayer insulating layer. The lower interlayer insulating layers 30 and the upper interlayer insulating layers 48 may constitute interlayer insulating layers 29. The lower mold layers 33 and the upper mold layers 51 may constitute mold layers.

An upper separation pattern 54 may be formed to penetrate through a portion of the preliminary upper stack structure 45. The upper separation pattern 54 may penetrate through one or a plurality of upper mold layers disposed above, among the upper mold layers 51. The upper separation pattern 54 may be formed of an insulating material such as silicon oxide.

In operation S30, upper vertical holes 57 may be formed to penetrate through the preliminary upper stack structure 45. The upper vertical holes 57 may be formed using a second photolithography process and a second etching process. The upper vertical holes 57 may expose the lower sacrificial layers 39 of FIG. 22.

In operation S35, the lower sacrificial layers (39 of FIG. 22) may be removed.

In operation S40, vertical structures VS may be formed in the lower and upper vertical holes 36 and 57. The vertical structures VS may be vertical structures according to one of the embodiments described with reference to FIGS. 1A to 20. The forming vertical structures VS may include forming liner layers 60 to conformally cover internal walls of the lower and upper vertical holes 36 and 57, forming an insulating core region 66 on the liner layers 60 to partially fill the lower and upper vertical holes 36 and 57, and forming a pad pattern 68 on the insulating core region 66.

Referring to, FIGS. 1A, 1B, 21, and 24, a first upper insulating layer 71 may be formed. In operation S45, separation trenches 74 may be formed. The separation trenches 74 may penetrate through the first upper insulating layer 71, the preliminary upper stack structure 45, the preliminary lower stack structure 27, and the lower and upper horizontal layers 21 and 24.

A material of the lower horizontal layer 21 may be replaced with silicon to form a lower horizontal layer 21a including the silicon layer.

In operation S50, the lower mold layers 33 and the upper mold layers 51 in the preliminary lower stack structure 27 and the preliminary upper stack structure 45 may be replaced with gate layers. For example, the lower mold layers 33 and the upper mold layers 51 may be removed to form voids, and gate layers may be formed in the voids. Each of the gate layers may include a gate dielectric 77 and a gate electrode 80. For example, the lower mold layers 33 in the preliminary lower stack structure 27 may be replaced with gate dielectrics 77 and lower gate electrodes 80a, and the upper mold layers 51 in the preliminary upper stack structure 45 may be replaced with gate dielectrics 77 and upper gate electrodes 80b.

In operation S55, separation structures 83 may be formed in the separation trenches 74.

Returning to FIGS. 1A, 1B, 2A, and 2B, in operation S60, an interconnection process may be performed. The interconnection process may be a process of forming the bitline contact plugs 89 and the bitlines 92 described above with reference to FIGS. 1A, 1B, 2A, and 2B.

When lower vertical holes 36 are formed to penetrate through a lower stack region ST_L by a first etching process and upper vertical holes 57 are formed to penetrate through an upper stack region ST_U by a second etching process, the semiconductor device 1 according to the above-described embodiments may provide a structure configured to prevent the upper vertical holes 57 from being misaligned with the lower vertical holes 36 as some of the upper vertical holes 57 are bent, e.g., to provide a misalignment margin to ensure sufficient contact even if the upper vertical holes 57 are somewhat misaligned relative to the lower vertical holes 36. For example, the various shapes in the various top views described with reference to FIGS. 3A to 19B may prevent the upper vertical holes 57 from being misaligned with the lower vertical holes 36 as some of the upper vertical holes 57 are bent.

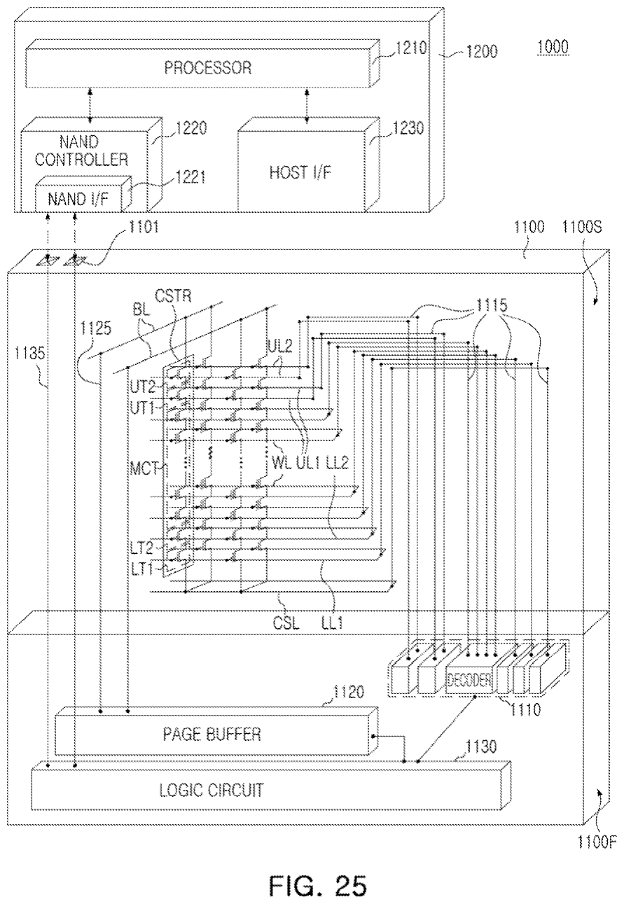

Data storage systems including a semiconductor device according to an example embodiment will now be described with reference to FIGS. 25, 26, and 27, respectively.

FIG. 25 is a schematic diagram of an electronic system including a semiconductor device according to an example embodiment.

Referring to FIG. 25, a data storage system 1000 according to an example embodiment may include a semiconductor device 1100 and a controller 1200 electrically connected to the semiconductor device 1100. The data storage system 1000 may be a storage device including the semiconductor device 1100 or an electronic device including a storage device. For example, the data storage system 1000 may be a solid state drive device (SSD), a universal serial bus (USB), a computing system, a medical device, or a communications device, including the semiconductor device 1100. In an example embodiment, the data storage system 1000 may be an electronic system storing data. The semiconductor device 1100 may be a semiconductor device according to one of the example embodiments described above with reference to FIGS. 1 to 24.

The semiconductor device 1100 may include a first structure 1100F and a second structure 1100S on the first structure 1100F. The first structure 1100F may be a peripheral circuit structure including a decoder circuit 1110, a page buffer 1120, and a logic circuit 1130. The second structure 1100S may be a memory structure including a bitline BL, a common source line CSL, wordlines WL, first and second gate upper lines UL1 and UL2, and first and second gate lower lines LL1 and LL2, and memory cell strings CSTR between the bitline BL and the common source line CSL.

In the second structure 1100S, each of the memory cell strings CSTR may include lower transistors LT1 and LT2 adjacent to the common source line CSL, upper transistors UT1 and UT2 adjacent to the bitline BL, and memory cell transistors MCT disposed between the lower transistors LT1 and LT2 and the upper transistors UT1 and UT2. The number of the lower transistors LT1 and LT2 and the number of the upper transistors UT1 and UT2 may vary according to example embodiments.

In example embodiments, the upper transistors UT1 and UT2 may include a string select transistor, and the lower transistors LT1 and LT2 may include a ground select transistor. The gate lower lines LL1 and LL2 may be gate electrodes of the lower transistors LT1 and LT2, respectively. The wordlines WL may be gate electrodes of the memory cell transistors MCT. The gate upper lines UL1 and UL2 may be gate electrodes of the upper transistors UT1 and UT2, respectively.

The above-described gate electrodes 80 may constitute the gate lower lines LL1 and LL2, the wordlines WL, and the gate upper lines UL1 and UL2.

In example embodiments, the lower transistors LT1 and LT2 may include a lower erase control transistor LT1 and a ground select transistor LT2 connected in series. The upper transistors UT1 and UT2 may include a string select transistor UT1 and an upper erase control transistor UT2 connected in series. At least one of the lower erase control transistor LT1 and the upper erase control transistor UT1 may be used for an erase operation to erase data stored in the memory cell transistors MCT based on gate induce drain leakage (GIDL).

The common source line CSL, the first and second gate lower lines LL1 and LL2, the wordlines WL, and the first and second gate upper lines UL1 and UL2 may be electrically connected to the decoder circuit 1110 through first connection lines 1115 extending from the first structure 1100F to the second structure 1100S.

The bitlines BL may be electrically connected to the page buffer 1120 through second connection lines 1125 extending from the first structure 1100F to the second structure 1100S. The bitlines BL may be the above-described bitlines 92.

In the first structure 1100F, the decoder circuit 1110 and the page buffer 1120 may perform a control operation on at least one selected memory cell transistor, among the plurality of memory cell transistors MCT. The decoder circuit 1110 and the page buffer 1120 may be controlled by the logic circuit 1130.

The semiconductor device 1100 may further include an input/output pad 1101. The semiconductor device 1100 may communicate with the controller 1200 through the input/output pad 1101 electrically connected to the logic circuit 1130. The input/output pad 1101 may be electrically connected to the logic circuit 1130 through an input/output connection line 1135 extending from the first structure 1100F to the second structure 1100S. Accordingly, the controller 1200 may be electrically connected to the semiconductor device 1100 through the input/output pad 1101 and may control the semiconductor device 1100.

The controller 1200 may include a processor 1210, a NAND controller 1220, and a host interface 1230. According to example embodiments, the data storage system 1000 may include a plurality of semiconductor devices 1100. In this case, the controller 1200 may control the plurality of semiconductor devices 1100.

The processor 1210 may control overall operation of the data storage system 1000 including the controller 1200. The processor 1210 may operate according to a predetermined firmware to access the semiconductor device 1100 by controlling the NAND controller 1220. The NAND controller 1220 may include a NAND interface 1221 for processing communication with the semiconductor device 1100. A control command for controlling the semiconductor device 1100, data to be written in the memory cell transistors MCT of the semiconductor device 1100, and data to be read from the memory cell transistors MCT of the semiconductor device 1100 may be transmitted through the NAND interface 1221. The host interface 1230 may provide a communication function between the data storage system 1000 and an external host. When a control command is received from an external host through the host interface 1230, the processor 1210 may control the semiconductor device 1100 in response to the control command.

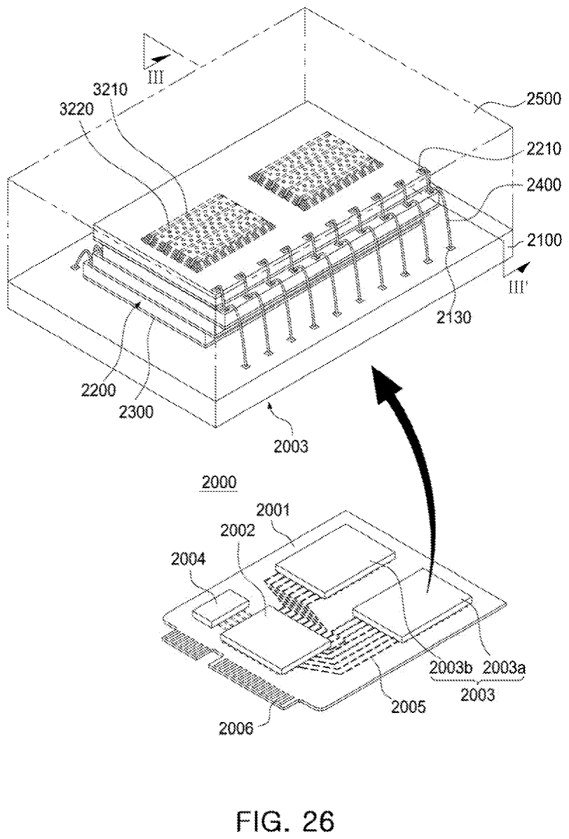

FIG. 26 is a schematic perspective view of a data storage system including a semiconductor device according to an example embodiment.

Referring to FIG. 26, a data storage system 2000 according to an example embodiment may include a main substrate 2001, a controller 2002 mounted on the main substrate 2001, one or more semiconductor packages 2003, and a DRAM 2004. The semiconductor package 2003 and the DRAM 2004 may be connected to the controller 2002 by interconnection patterns 2005 formed on the main substrate 2001.

The main substrate 2001 may include a connector 2006 including pins coupled to an external host. The number and arrangement of the pins in the connector 2006 may vary depending on a communication interface between the data storage system 2000 and the external host. In example embodiments, the data storage system 2000 may communicate with an external host according to one of interfaces such as a universal serial bus (USB), peripheral component interconnect express (PCI-Express), serial advanced technology attachment (SATA), and M-PHY for universal flash storage (UFS). In example embodiments, the data storage system 2000 may operate by power supplied from an external host through the connector 2006. The data storage system 2000 may further include a power management integrated circuit (PMIC) distributing power, supplied from the external host, to the controller 2002 and the semiconductor package 2003.

The controller 2002 may write data in the semiconductor package 2003 or may read data from the semiconductor package 2003, and may improve an operation speed of the data storage system 2000.

The DRAM 2004 may be implemented by a buffer memory for reducing a difference in speed between the semiconductor package 2003, a data storage space, and an external host. The DRAM 2004 included in the data storage system 2000 may also operate as a type of cache memory, and may provide a space for temporarily storing data in a control operation performed on the semiconductor package 2003. When the DRAM 2004 is included in the data storage system 2000, the controller 2002 may further include a DRAM controller controlling the DRAM 2004, in addition to the NAND controller controlling the semiconductor package 2003.

The semiconductor package 2003 may include first and second semiconductor packages 2003a and 2003b spaced apart from each other. The first and second semiconductor packages 2003a and 2003b may each be a semiconductor package including a plurality of semiconductor chips 2200. Each of the semiconductor chips 2200 may include the semiconductor device described in one of the example embodiments described above with reference to FIGS. 1 to 24.

Each of the first and second semiconductor packages 2003a and 2003b may include a package substrate 2100, semiconductor chips 2200 on the package substrate 2100, adhesive layers 2300 on a lower surface of each of the semiconductor chips 2200, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210.

In example embodiments, the connection structure 2400 may be a bonding wire electrically connecting the input and output pad 2210 to the package upper pads 2130. Accordingly, in each of the first and second semiconductor packages 2003a and 2003b, the semiconductor chips 2200 may be electrically connected to each other by a bonding wire method and may be electrically connected to the package upper pads 2130 of the package substrate 2100. In example embodiments, in each of the first and second semiconductor packages 2003a and 2003b, the semiconductor chips 2200 may be electrically connected to each other by a connection structure including a through-silicon via (TSV), instead of the connection structure 2400 of a bonding wire method.

In example embodiments, the controller 2002 and the semiconductor chips 2200 may be included in a single package. For example, the controller 2002 and the semiconductor chips 2200 may be mounted on an interposer substrate different from the main substrate 2001, and the controller 2002 may be connected to the semiconductor chips 2200 through an interconnection formed on the interposer substrate.

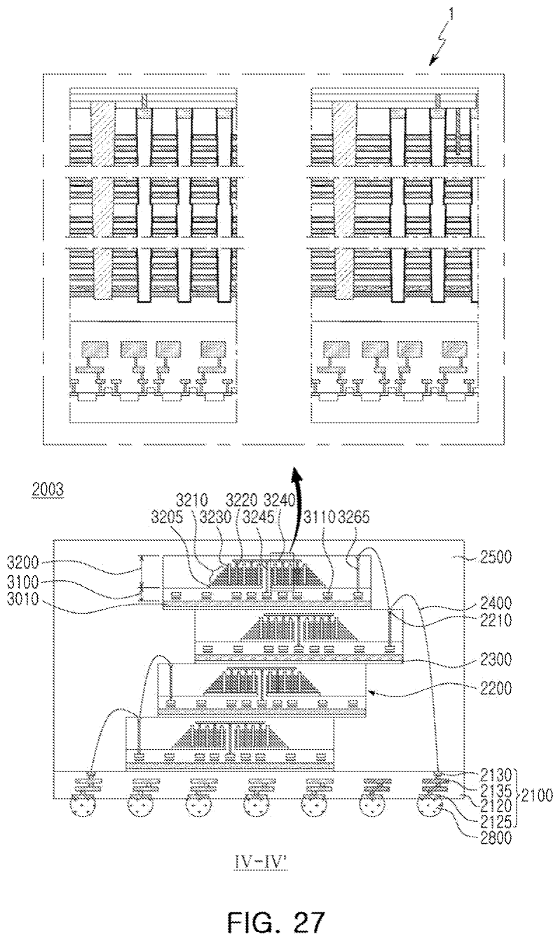

FIG. 27 is a schematic cross-sectional view of a data storage system including a semiconductor device according to an example embodiment. FIG. 27 illustrates an example embodiment of the semiconductor package 2003 of FIG. 26, and conceptually illustrates a cross-sectional region of the semiconductor package 2003 illustrated in FIG. 26 taken along line III-III′.

Referring to FIG. 27, in the semiconductor package 2003, the package substrate 2100 may be a printed circuit board. The package substrate 2100 may include a package substrate body portion 2120, package upper pads 2130 on an upper surface of the package substrate body portion 2120, lower pads 2125 on a lower surface of the package substrate body portion 2120 or exposed through the lower surface, and internal interconnections 2135 electrically connecting the package upper pads 2130 to the lower pads 2125 in the package substrate body portion 2120. The package upper pads 2130 may be electrically connected to the connection structures 2400. The lower pads 2125 may be connected to interconnection patterns 2005 of a main substrate 2001 of the data storage system 2000 through conductive connection portions 2800 as illustrated in FIG. 26.

Each of the semiconductor chips 2200 may include a semiconductor substrate 3010, and a first structure 3100 and a second structure 3200 stacked in order on the semiconductor substrate 3010. The first structure 3100 may include a peripheral circuit region including peripheral interconnections 3110. The second structure 3200 may include a common source line 3205, a gate stack structure 3210 on the common source line 3205, memory channel structures 3220 and separation structures 3230 penetrating through the gate stack structure 3210, bitlines 3240 electrically connected to the memory channel structures 3220, and gate connection lines (94 of FIG. 25) electrically connected to wordlines (WL of FIG. 25) of the gate stack structure 3210. The gate stack structure 3210 may be the above-described stack structure ST. The memory channel structures 3220 may be the above-described vertical memory structures VMS.

The first structure 3100 may include the first structure 1100F of FIG. 25. The second structure 3200 may include the second structure 1100S of FIG. 25. For example, in FIG. 27, a partially enlarged portion, indicated by reference numeral “1”, may indicate the cross-sectional structure illustrated in FIG. 2A. Accordingly, each of the semiconductor chips 2200 may include the semiconductor device 1 according to one of the example embodiments described above with reference to FIGS. 1 to 24.

Each of the semiconductor chips 2200 may include a through-interconnection 3245 electrically connected to the peripheral interconnections 3110 of the first structure 3100 and extending inwardly of the second structure 3200. The through-interconnection 3245 may penetrate through the gate stack structure 3210, and may also be on an external side of the gate stack structure 3210. Each of the semiconductor chips 2200 may further include an input/output connection line 3265, electrically connected to the peripheral interconnections 3110 of the first structure 3100 and extending inwardly of the second structure, and an input/output pad 2210 electrically connected to the input/output connection line 3265.

As described above, according to example embodiments, a semiconductor device which may improve integration density may be provided. Example embodiments may provide a semiconductor device having one or more of improved integration density and improve reliability, and a data storage system including the same.

When lower vertical holes are formed to penetrate through a lower stack region by a first etching process and upper vertical holes are formed to penetrate through an upper stack region by a second etching process, some of the upper vertical holes may be bent to be misaligned with the lower vertical holes. Example embodiments may provide a semiconductor device which may prevent the misalignment between the upper vertical holes and the lower vertical holes.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a base;
a stack structure including a first stack region and a second stack region on the first stack region, on the base;
first and a second separation structures penetrating through the stack structure in a vertical direction, perpendicular to an upper surface of the base, and parallel to each other, on the base; and
vertical structures penetrating through the stack structure in the vertical direction, and between the first and second separation structures, wherein:
each of the first and second stack regions includes interlayer insulating layers and gate electrodes alternately and repeatedly stacked in the vertical direction;
at least one of the gate electrodes in the first stack region includes a first wordline and at least one of the gate electrodes in the second stack region includes a second wordline;
the vertical structures include a first vertical memory structure and a second vertical memory structure spaced apart from the first separation structure by different lengths;
each of the first and second vertical memory structures includes a lower vertical portion penetrating through the first stack region, and an upper vertical portion extending from the lower vertical portion and penetrating through the second stack region; and
a first distance between a center of an upper region of the upper vertical portion of the first vertical memory structure and a center of an upper region of the upper vertical portion of the second vertical memory structure is different from a second distance between a center of an upper region of the lower vertical portion of the first vertical memory structure and a center of an upper region of the lower vertical portion of the second vertical memory structure.

2. The semiconductor device as claimed in claim 1, wherein:
a distance between the first separation structure and the first vertical memory structure is smaller than a distance between the first separation structure and the second vertical memory structure; and
the first distance between the center of the upper region of the upper vertical portion of the first vertical memory structure and the center of the upper region of the upper vertical portion of the second vertical memory structure is smaller than the second distance between the center of the upper region of the lower vertical portion of the first vertical memory structure and the center of the upper region of the lower vertical portion of the second vertical memory structure.

3. The semiconductor device as claimed in claim 1, wherein, in a top view, a distance between the center of the upper region of the upper vertical portion of the first vertical memory structure and the center of the upper region of the lower vertical portion of the first vertical memory structure is greater than a distance between the center of the upper region of the upper vertical portion of the second vertical memory structure and the center of the upper region of the lower vertical portion of the second vertical memory structure.

4. The semiconductor device as claimed in claim 1, wherein, in a top view, the upper region of the upper vertical portion of the first vertical memory structure is elliptical shape, and the upper region of the upper vertical portion of the second vertical memory structure is elliptical shape or circular shape.

5. The semiconductor device as claimed in claim 1, wherein, in a top view, a maximum width of the upper region of the upper vertical portion of the first vertical memory structure is greater than a maximum width of the upper region of the upper vertical portion of the second vertical memory structure.

6. The semiconductor device as claimed in claim 4, wherein, in a top view, each of the first and second separation structures extends in a first direction, parallel to the upper surface of the base, and a major-axis direction of the upper region of the upper vertical portion of the first vertical memory structure intersects the first direction.

7. The semiconductor device as claimed in claim 1, wherein:
a width of the upper region of the upper vertical portion of the first vertical memory structure is greater than a width of a lower region of the upper vertical portion of the first vertical memory structure;
a width of the upper region of the lower vertical portion of the first vertical memory structure is greater than the width of the lower region of the upper vertical portion of the first vertical memory structure;
a width of the upper region of the upper vertical portion of the second vertical memory structure is greater than a width of a lower region of the upper vertical portion of the second vertical memory structure; and
a width of the upper region of the lower vertical portion of the second vertical memory structure is greater than the width of the lower region of the upper vertical portion of the second vertical memory structure.

8. The semiconductor device as claimed in claim 1, wherein:
the base includes a first silicon layer;
each of the vertical structures includes an insulating core region, a channel layer on a side surface of the insulating core region, a dielectric structure on a side surface of the channel layer, and a pad pattern connected to the channel layer and on the insulating core region; and
each of the vertical structures include a portion extending inwardly of the first silicon layer.

9. The semiconductor device as claimed in claim 8, wherein:
the base further includes a second silicon layer on the first silicon layer;
the vertical structures penetrate through the second silicon layer; and
the second silicon layer penetrates through the dielectric structure and is in contact with the channel layer.

10. The semiconductor device as claimed in claim 1, further comprising a peripheral circuit chip on the stack structure, wherein:
the peripheral circuit chip includes:
a semiconductor substrate;
a peripheral circuit below the semiconductor substrate; and
a peripheral interconnection below the peripheral circuit; and
the peripheral circuit and the peripheral interconnection are disposed between the semiconductor substrate and the stack structure.

11. The semiconductor device as claimed in claim 1, further comprising gate contact plugs, wherein:
the gate electrodes extend in a first direction and include gate pads arranged in a staircase shape;
the gate contact plugs are in contact with the gate pads;
the gate contact plugs include a first gate contact plug and a second gate contact plug;
the first gate contact plug includes a first lower gate plug portion and a first upper gate plug portion on the first lower gate plug portion;
the second gate contact plug includes a second lower gate plug portion and a second upper gate plug portion on the second lower gate plug portion; and
a distance between a center of an upper region of the first upper gate plug portion and a center of an upper region of the second upper gate plug portion is different from a distance between a center of an upper region of the first lower gate plug portion and a center of an upper region of the second upper gate plug portion.

12. The semiconductor device as claimed in claim 1, further comprising:
a semiconductor substrate below the base;
a peripheral circuit on the semiconductor substrate;
a peripheral interconnection on the peripheral circuit; and
peripheral contact plugs electrically connected to the peripheral interconnection, wherein:
the peripheral circuit and the peripheral interconnection are disposed between the semiconductor substrate and the base;
an upper surface of each of the peripheral contact plugs is on a level higher than a level of an upper surface of each of the vertical structures, and a lower surface of each of the peripheral contact plugs is on a level lower than a level of a lowermost gate electrode, among the gate electrodes;
the peripheral contact plugs include a first peripheral contact plug and a second peripheral contact plug;
the first peripheral contact plug includes a first lower peripheral plug portion and a first upper peripheral plug portion on the first lower peripheral plug portion;
the second peripheral contact plugs includes a second lower peripheral plug portion and a second upper peripheral plug portion on the second lower peripheral plug portion; and
a distance between a center of an upper region of the first upper peripheral plug portion and a center of an upper region of the second upper peripheral plug portion is different from a distance between a center of an upper region of the first lower peripheral plug portion and a center of an upper region of the second upper peripheral plug portion.

13. The semiconductor device as claimed in claim 1, wherein, in a top view, in at least one of the first and second vertical memory structures, the upper region of the lower vertical portion is in a form of an ellipse having a first major axis and a first minor axis, and the upper region of the upper vertical portion is in a form of an ellipse having a second major axis, intersecting the first major axis, and a second minor axis intersecting the first minor axis.

14. A semiconductor device, comprising:
a base;
a stack structure including a first stack region and a second stack region on the first stack region, on the base;
first and second separation structures penetrating through the stack structure in a vertical direction, perpendicular to an upper surface of the base, and parallel to each other, on the base;
vertical memory structures penetrating through the stack structure in the vertical direction, and between the first and second separation structures; and
bitline contact plugs electrically connected to the vertical memory structures and on the vertical memory structures, wherein:
each of the first and second separation structures extends in a first direction, parallel to the upper surface of the base;
each of the first and second stack regions includes interlayer insulating layers and gate electrodes stacked alternately and repeatedly in the vertical direction;
the vertical memory structures include:
a first vertical memory structure spaced apart from the first separation structure by a first distance;
a second vertical memory structure spaced apart from the first separation structure by a second distance greater than the first distance;
a third vertical memory structure spaced apart from the first separation structure by a third distance greater than the second distance; and
a fourth vertical memory structure spaced apart from the first separation structure by a fourth distance greater than the third distance;
the first and third vertical memory structures are arranged in a second direction, perpendicular to the first direction;
the second and fourth vertical memory structures are arranged in the second direction;
in a top view, a first virtual axis passing through centers of the first and third vertical memory structures is spaced apart from a second virtual axis passing through centers of the second and fourth vertical memory structures in the first direction,
each of the first to fourth vertical memory structures includes a lower vertical portion, penetrating through the first stack region, and an upper vertical portion extending from the lower vertical portion and penetrating through the second stack region; and
a first distance between a center of an upper region of the upper vertical portion of the first vertical memory structure and a center of an upper region of the upper vertical portion of the second vertical memory structure is different from a second distance between a center of an upper region of the lower vertical portion of the first vertical memory structure and a center of an upper region of the upper vertical portion of the second vertical memory structure.

15. The semiconductor device as claimed in claim 14, wherein the first distance is smaller than the second distance.

16. The semiconductor device as claimed in claim 14, further comprising a vertical support structure spaced apart from the first separation structure by a fifth distance greater than the first distance, wherein the vertical support structure is electrically separated from the bitline contact plugs and is in an intermediate region between the first separation structure and the second separation structure.

17. The semiconductor device as claimed in claim 14, wherein, in a top view, a maximum width of the upper region of the upper vertical portion of the first vertical memory structure is greater than a maximum width of the upper region of the upper vertical portion of at least one of the second to fourth vertical memory structures.

18. The semiconductor device as claimed in claim 14, wherein:
in a top view, the upper region of the lower vertical portion of the first vertical memory structure is in a form of an ellipse having a first major-axis direction;
an upper region of the upper vertical portion of at least one of the second to fourth vertical memory structures is in a form of an ellipse having a second major-axis direction; and
the second major-axis direction has an orientation intersecting the first major-axis direction.

19. The semiconductor device as claimed in claim 14, wherein, in a top view, in at least one of the first to fourth vertical structures, the upper region of the lower vertical portion is in a form of an ellipse having a first major axis and a first minor axis, and the upper region of the upper vertical portion is in a form of an ellipse having a second major axis, intersecting the first major axis, and a second minor axis intersecting the first minor axis.

20. A data storage system, comprising:
a semiconductor device including an input/output pad; and
a controller electrically connected to the semiconductor device through the input/output pad and configured to control the semiconductor device, wherein:
the semiconductor device includes:
a base;
a stack structure including a first stack region and a second stack region on the first stack region, on the base;
first and second separation structures penetrating through the stack structure in a vertical direction, perpendicular to an upper surface of the base, and parallel to each other, on the base;
vertical memory structures penetrating through the stack structure in the vertical direction, and between the first and second separation structures; and
bitline contact plugs electrically connected to the vertical memory structures and on the vertical memory structures, wherein:
each of the first and second separation structures extends in a first direction, parallel to the upper surface of the base;
each of the first and second stack regions includes interlayer insulating layers and gate electrodes stacked alternately and repeatedly in the vertical direction;
the vertical memory structures include:
a first vertical memory structure spaced apart from the first separation structure by a first distance;
a second vertical memory structure spaced apart from the first separation structure by a second distance greater than the first distance;
a third vertical memory structure spaced apart from the first separation structure by a third distance greater than the second distance; and
a fourth vertical memory structure spaced apart from the first separation structure by a fourth distance greater than the third distance;
the first and third vertical memory structures are arranged in a second direction, perpendicular to the first direction;
the second and fourth vertical memory structures are arranged in the second direction;
in a top view, a first virtual axis passing through centers of the first and third vertical memory structures is spaced apart from a second virtual axis passing through centers of the second and fourth vertical memory structures in the first direction,
each of the first to fourth vertical memory structures includes a lower vertical portion, penetrating through the first stack region, and an upper vertical portion extending from the lower vertical portion and penetrating through the second stack region; and
a first distance between a center of an upper region of the upper vertical portion of the first vertical memory structure and a center of an upper region of the upper vertical portion of the second vertical memory structure is different from a second distance between a center of an upper region of the lower vertical portion of the first vertical memory structure and a center of an upper region of the upper vertical portion of the second vertical memory structure.
